(19) United States
(12) Patent Application Publication
(10) Pub. No.: US 2007/0020795 A1
(43) Pub. Date: Jan. 25, 2007

(54) Solid-state imaging device and its manufacturing method

(76) Inventors: Mitsuyoshi Mori, Kyoto (JP); Takumi Yamaguchi, Kyoto (JP); Shinji Yoshida, Osaka (JP)

Correspondence Address: MCDERMOTT WILL & EMERY LLP, 600 13TH STREET, NW, WASHINGTON, DC, 20005-3096, US

(21) Appl. No.: 10/568,961

(22) PCT Filed: Jan. 7, 2005
(86) PCT No.: PCT/JP05/00129

§ 371 Date: Feb. 22, 2006

(30) Foreign Application Priority Data
Jan. 19, 2004 (JP) 2004-010715
Jan. 19, 2004 (JP) 2004-010718
Jan. 19, 2004 (JP) 2004-010723
Mar. 2, 2004 (JP) 2004-057260

(51) Int. Cl. H01L 21/00

(52) U.S. Cl. 438/57

(57) ABSTRACT

In a method for manufacturing a solid-state imaging device of the present invention, a pad insulting film 2 made of an oxide film and an anti-oxidizing film 3 made of a nitride film are deposited on a n-type semiconductor substrate 1. Then, an opening 4 is formed to expose an element isolation formation region of the semiconductor substrate 1. Next, an anti-oxidizing film (not shown) for burying the opening 4 is formed on the substrate and anisotropic etching is performed to form a sidewall 5. Subsequently, a trench 6 is formed using the anti-oxidizing film 3 and the sidewall 5 as a mask. Then, a p-type impurity is implanted into a part of the semiconductor substrate 1 which is exposed at the side face of the trench 6 and a thermal oxide film is formed in the surface portion of the trench 6 in the semiconductor substrate 1. Thereafter, the trench 6 is buried with a burying film 8.

### TECHNICAL FIELD

The present invention relates to a solid-state imaging device and a method for manufacturing it, and particularly relates to a solid-state imaging device in which an imaging region having a plurality of pixels are provide in a semiconductor substrate and a method for manufacturing it.

### BACKGROUND ART

MOS solid-state imaging devices are image sensors for reading a signal supplied to each pixel by amplifying the signal by an amplification circuit including a MOS transistor. In the solid-state imaging devices, a sensor manufactured by the MOS process, namely, a generally-called CMOS image sensor operates at low voltages, consumes less power, and is integrated in one chip with a peripheral circuit. In this connection, recently, the CMOS image censors become a focus of attention as image input elements for portable equipment such as compact cameras for personal computers.

FIG. 10 is a circuit diagram showing one example of a construction of a solid-state imaging device. This solid-state imaging device includes, on a substrate, a imaging region 107 in which a plurality of pixels 106 are arranged in matrix, a vertical sift register 108 and a horizontal shift register 109 each for selecting a pixel, and a timing generator 110 for supplying a necessary pulse to the vertical shift register 108 and the horizontal shift register 109.

In each of the pixels 106 arranged in the imaging region 107, there are provided: a photoelectric conversion section 101 made of photodiode; a transfer transistor 102 of which source is connected to the photoelectric conversion section 101, of which drain is connected to the gate of an amplification transistor 104, and of which gate is connected to an output pulse wire 111 from the vertical shift register 108; a reset transistor 103 of which source is connected to the drain of the transfer transistor 102, of which gate is connected to an output pulse wire 112 from the vertical shift register 108, and of which drain is connected to a power source 113; the amplification transistor 104 of which drain is connected to the power source 113 and of which gate is connected to the drain of the transfer transistor 102 and the source of the reset transistor 103; and a selection transistor 105 of which drain is connected to the source of the amplification transistor 104, of which gate is connected to an output pulse wire 114 from the vertical shift register 108 and of which source is connected to a signal wire 115.

In the imaging region 107, in the case where LOCOS or STI (Shallow Trench Isolation) is formed in the element isolation region, defects are liable to be caused due to film stress of a nitride film and the like and long-time high-temperature thermal treatment. The defects serve as a factor of a dark current and a white flaw. Further, with the LOCOS, the bird's beak becomes long, inviting difficulty in miniaturization of the imaging region 107. In contrast, with the STI, stress due to existence of a buried oxide film is caused.

For solving the above problems, a conventional technique disclosed in Patent Document 1 has been proposed. This conventional technique will be explained with reference to FIG. 11(a) to FIG. 11(f). FIG. 11(a) to FIG. 11(f) are sections showing steps for forming an element isolation region in a conventional imaging device.

First, in the step shown in FIG. 11(a), a gate insulating film 52 having a thickness of 0.1 μm is formed by subjecting the upper portion of a semiconductor substrate 51 to thermal oxidation. Next, an element isolation region 53, a photoelectric conversion section 54, and a drain region 55 are formed in the upper part of the semiconductor substrate 51 by ion implantation over the gate insulating film 52. Herein, a p-type impurity is ion implanted in the element isolation region 53 if a n-type impurity is ion implanted in the photoelectric conversion section 54 and a drain region 55.

Subsequently, in the step shown in FIG. 11(b), a CVD oxide film 56 having a thickness of about 0.3 μm is deposited on the gate insulating film 52.

Thereafter, in the step shown in FIG. 11(c), a resist (not shown) including an opening portion in a region corresponding to a region where a gate electrode is to be formed is formed on the CVC oxide film 56. Etching is performed using the resist as a mask by RIE (Reactive Ion Etching) to form a trench 57 passing through the CVD oxide film 56.

Next, in the step shown in FIG. 11(d), a polysilicon film 58 is formed for burying the trench 57 (shown in FIG. 11(c)).

Subsequently, in the step shown in FIG. 11(e), a resist (not shown) including a trench of which inner diameter is larger than that of the trench 57 is formed on the polysilicon film 58. Then, the polysilicon film 58 (shown in FIG. 11(d)) is subjected to RIE using the resist as a mask to form a wiring pattern 58a including a gate electrode.

Thereafter, in the step shown in FIG. 11(f), an interlayer insulating film 59 of SiO₂ or the like is deposited on the gate insulating film 52 and the wiring pattern 58a. Then, RIE is performed to form a trench passing through the interlayer insulating film 59 and reaching the drain region 55 and the trench is buried with an electric conductor, thereby forming a signal wire 60.

Patent Document 1: Japanese Patent Application Laid Open Publication No. 10-373818A

Patent Document 2: Japanese Patent Application Laid Open Publication No. 2000-196057A

### DISCLOSURE OF THE INVENTION

Means of Solving the Problems

However, the above-described conventional method of manufacturing a solid-state imaging device involves the following disadvantages.

In order to form an implanted layer of the element isolation region 53 by ion implantation as described above, it is necessary to set the width of an implanted layer of the channel stop to be larger for sufficiently ensuring isolation power as the element isolation region. However, larger width of the element isolation region 53 runs counter to a demand for miniaturization of the solid-state imaging device.

On the contrary, if the width of the implanted layer of the channel stop is set small while the dose amount of ion impurity is increased for ensuring the isolation power, a leak current increases at the PN junction between the photoelectric conversion section 54 and the element isolation region 53. This invites increase in dark current and white flaws.

The present invention has its object of providing a solid-state imaging device capable of being miniaturized, lowering a cark current, and reducing the number of white flaws while ensuring isolation power of an element isolation region, and a method for manufacturing it.

Means of Solving the Problems

The first method of the present invention is a method for manufacturing a solid-state imaging device in which an imaging region in which a plurality of unit pixels are arranged is provided on a semiconductor substrate, each of the unit pixel including a plurality of element formation regions and an element isolation formation region located between the plurality of element formation regions, wherein the method includes: a step (a) of forming, on the semiconductor substrate, a protection film including an opening portion that exposes the element isolation formation region and a region located beside the element isolation formation region of the semiconductor substrate; a step (b) of forming a sidewall on a side face of the opening in the protection film; a step (c) of forming a trench in the element isolation formation region in the semiconductor substrate by etching using the protection film and the sidewall as a mask; and a step (d) of forming an element isolation region by burying the trench with a burying film.

In the above method, the trench is formed by etching using the sidewall as a mask in the step (c), so that the width of the trench can be made smaller by the thickness of the sidewall than the width of the opening in the protection film. Consequently, even in the case where the opening of the protection film is formed to have a minimum opening width that can be formed by the currently available patterning method, a trench further narrower than the minimum opening width can be formed.

The element isolation power of the burying film for burying the trench is high even in the narrowed trench, thereby ensuring the element isolation power. The narrow trench width leads to extension of the distance between the element formation regions and the element isolation by the narrowed width. Accordingly, even if thermal stress is generated in the vicinity of the trench after the trench is buried with the burying film, the leak current flowing towards the element formation regions can be reduced. Hence, the dark current and white flaws are obviated.

The element formation regions of the semiconductor substrate may include a n-type impurity and the method may further include the step of implanting a p-type ion into a surface portion of the trench in the semiconductor substrate after the step (c) and before the step (d). In this case, the dark current is prevented from flowing towards the active region through the interface state generated by the formation of the trench. In detail, by doping the p-type impurity in the vicinity of the surface of the trench in the semiconductor substrate, an energetic barrier is formed between the vicinity of the surface of the trench and the active region of the element, thereby restricting the movement of the carrier.

The method may further include the step of oxidizing a surface portion of the trench in the semiconductor substrate after the step (c) and before the step (d).

In the step (a), a first insulating film and a second insulating film provided on the first insulating film and having a property of oxidization resistance may be formed as the protection film.

In the step (d), the burying film can be deposited by CVD.

In the step (d), a level of the element isolation may be allowed to be higher than an upper face of the semiconductor substrate by removing the protection film deeper than the burying film after the burying film is formed so as to bury the opening of the protection film. In this case, though a wiring such as a gate wiring is formed on the burying layer, short circuit between wirings to be isolated therebetween can be prevented. The reason thereof will be described below. The wirings are formed in such a manner that the semiconductor substrate and the burying film are covered with the conducting film and the conducting film is patterned. If the burying film is formed to a level lower than the upper face of the semiconductor substrate, it is difficult to remove a part of the conducting film which is located on the burying film. If this is the case, the wirings to be isolated from each other are liable to be in contact with each other through the conducting film that could not be removed. While, the higher burying film obviates this liability.

A peripheral circuit region including a drive circuit for operating the imaging region may be provided beside the imaging region in the semiconductor substrate and an element isolation of the peripheral circuit region may be formed by the same step as the step of forming the element isolation of the imaging region. In this case, the steps can be simplified.

In the peripheral circuit, only a NMOS transistor, only a PMOS transistor, or a CMOS transistor can be formed.

The second method of the present invention is a method for manufacturing a solid-state imaging device in which an imaging region in which a plurality of unit pixels are arranged is provided on a semiconductor substrate, each of the unit pixel including a plurality of element formation regions and an element isolation formation region located between the plurality of element formation regions, wherein the method includes: a step (a) of forming, on the semiconductor substrate, a protection film including an opening portion that exposes at least a part of the element isolation formation region of the semiconductor substrate; a step (b) removing and patterning the part of the element isolation formation region of the semiconductor substrate by etching using the protection film as a mask after the step (a); a step (c) of forming an oxide film for element isolation by oxidizing a surface portion of the patterned element isolation formation region of the semiconductor substrate after the step (b); and a step (d) of removing at least a part of the protection film after the step (c).

In this way, the oxidation after the formation of the concave prevents a bird's beak from being formed, contemplating miniaturization of the device. Further, the oxide film for element isolation is formed by oxidizing the surface portion of the concave, and therefore, the oxide film is formed in a region apart from the element formation regions. This reduces stress in the region near the element formation regions and hardly generates film stress of the nitride film and the like and defects caused due to thermal treatment, attaining a solid-state imaging device having sufficient element isolation power with less dark current and less white flaws which are generated due to defects.

In the step (a), a pad insulating film and an anti-oxidizing film located above the pad insulating film nay be formed as the protection film.

In the step (a), an oxidizing film may be interposed between the padding insulating film and the anti-oxidizing film. In this case, thickness adjustment of the oxidizing film leads to efficient rounding of the corner of the semiconductor substrate.

By removing by etching a part of the oxide film for element isolation after the step (c), miniaturized pattern can be formed.

Inn the step (c), a bird's beak would be formed in a surface portion of the semiconductor substrate. In this case, removal of a part of the bird's beak after the step (c) shortens the bird's beak, and in turn, the active region becomes large in area.

A n-type impurity may be included in the element formation regions of the semiconductor substrate and the method may further include the step of implanting a p-type ion into a surface portion of the patterned element isolation formation region of the semiconductor substrate after the step (b) and before the step (c). In this case, the dark current is prevented from flowing towards an active region through the interface state generated by the formation of the concave. In detail, by doping the p-type impurity in the vicinity of the surface of the concave in the semiconductor substrate, an energetic barrier is formed between the vicinity of the surface of the concave and the active region of the element, thereby restricting the movement of the carrier.

In the step (a), if a width of the opening portion is set narrower than a width of the element isolation formation region, the oxide film does not become larger than a volume necessary for obtaining required element isolation power though the oxide film for element isolation expands in the horizontal direction and the perpendicular direction.

In the step (d), it is preferable to set a level of the element isolation formation region to be higher than an upper face of the semiconductor substrate by removing the protection film to a level deeper than an upper face of the oxide film for element isolation. In this case, though a wiring such as a gate wiring is formed on the element isolation oxide film, short circuit between wirings to be isolated therebetween can be prevented. The reason thereof will be described below. The wirings are formed in such a manner that the semiconductor substrate and the oxide film for element isolation are covered with the conducting film and the conducting film is patterned. If the oxide film for element isolation is formed to a level lower than the upper face of the semiconductor substrate, it is difficult to remove a part of the conducting film which is located on the oxide film for element isolation. If this is the case, the wirings to be isolated from each other are liable to be in contact with each other through the conducting film that could not be removed. While, the higher oxide film for element isolation obviates this liability.

A peripheral circuit region including a drive circuit for operating the imaging region may be provided beside the imaging region in the semiconductor substrate, and an element isolation region of the peripheral circuit region may be formed by the same step as a step of forming an element isolation region of the imaging region. In this case, the steps can be simplified.

In the peripheral circuit region, only a NMOS transistor, only a PMIS transistor, or a CMOS transistor can be formed. In this case, the number of implanting steps can be reduced, thus simplifying the steps.

The third method of the present invention is a method for manufacturing a solid-state imaging device in which an imaging region in which a plurality of unit pixels are arranged is provided on a semiconductor substrate, each of the unit pixel including a plurality of element formation regions and an element isolation formation region located between the plurality of element formation regions, wherein the method includes: a step (a) of forming, on the semiconductor substrate, a protection film including an opening portion that exposes the element isolation formation region of the semiconductor substrate; a step (b) of forming a trench by removing a part of the element isolation formation region of the semiconductor substrate by etching using the protection film as a mask; a step (c) of removing the protection film after the step (b); and a step (d) of performing thermal treatment in an atmosphere including hydrogen at a temperature in a range between 1000° C. and 1300° C., both inclusive, after the step (b).

In the above method, the upper part of the trench is covered with the semiconductor material composing the semiconductor substrate with the cavity left in the lower part of the trench in the step (d). With the cavity left in the element isolation formation region, stress generation is suppressed even under high-temperature thermal treatment. This stress reduction suppresses defect generation, suppressing dark current and white flaws.

The method may further include a step (e) of implanting an impurity having a conductivity type different from that of the element formation regions into the semiconductor film after the step (d). In this case, the semiconductor film separates the plurality of element formation regions electrically, ensuring sufficient breakdown voltage of the element isolation.

Alternatively, the method may further include a step (f) of oxidizing the semiconductor film after the step (d). In this case, the semiconductor film serves as an insulating film, so that the plurality of element formation regions are separated from each other electrically, ensuring sufficient breakdown voltage of the element isolation.

The method may further include a step (g) of subjecting a side face portion of the trench in the semiconductor substrate to thermal oxidation after the step (b) and before the step (d). In this case, damage caused at the formation of the trench can be remedied, so that the leak current induced due to the interface state can be reduced.

Alternatively, the method may further include a step (h) of forming an insulating film on a side face of the trench after the step (b) and before the step (d). In this case, the damage caused on the side face of the trench at the formation of the trench can be covered, so that the leak current induced due to the interface state can be reduced.

A part of the element formation regions of the semiconductor substrate may include a n-type impurity and the method may further include a step (i) of implanting a p-type ion into a surface portion of the trench in the semiconductor substrate after the step (b) and before the step (d). In this case, the breakdown voltage of the isolation can be increased.

A peripheral circuit region including a drive circuit for operating the imaging region may be provided beside the imaging region in the semiconductor substrate and an element isolation region of the peripheral circuit region may be formed by the same step as a step of forming an element isolation region of the imaging region. In this case, the steps can be simplified.

In the peripheral circuit region, only a NMOS transistor, only a PMOS transistor, or a CMOS transistor may be formed. In this case, the number of implanting steps is reduced, enabling simplification of the steps.

The fourth method of the present invention is a method for manufacturing a solid-state imaging device in which an imaging region in which a plurality of unit pixels are arranged is provided on a semiconductor substrate, each of the unit pixel including a plurality of element formation regions and an element isolation formation region located between the plurality of element formation regions, wherein the method includes: a step (a) of forming, on the semiconductor substrate, a protection film including an opening portion that exposes a part of the element isolation formation region of the semiconductor substrate; a step (b) of forming a trench having a depth two time larger than a width thereof by removing a part of the element isolation formation region of the semiconductor substrate by etching using the protection film as a mask; and a step (c) of forming a TEOS film for burying the trench by CVD after the step (b).

Accordingly, in the step (c), a cavity is easily formed at a part within the TEOS film. With the cavity formed, stress that the TEOS film gives to the semiconductor substrate can be reduced. This stress reduction suppresses defect generation, resulting in lowering of the dark current and suppression of white flaws. As well, the TEOS film and the cavity function to ensure the sufficient breakdown voltage of the element isolation.

The method may further include a step (d) of subjecting a side face portion of the trench in the semiconductor substrate to thermal oxidation after the step (b) and before the step (c). In this case, damage caused at the formation of the trench can be remedied, so that the leak current induced due to the interface state can be reduced.

Alternatively, the method may further include a step (e) of forming an insulting film on a side face of the trench after the step (b) and before the step (c). In this case, the surface of the trench at which damage is caused at the formation of the trench can be covered, so that the leak current induced due to the interface state can be reduced.

A n-type impurity may be included in a part of the element formation regions of the semiconductor substrate and the method may further include a step (f) of implanting a p-type ion into a part of a surface portion of the trench in the semiconductor substrate after the step (b) and before the step (c). In this case, the breakdown voltage of the isolation can be increased.

A peripheral circuit region including a drive circuit for operating the imaging region may be provided beside the imaging region in the semiconductor substrate and an element isolation region of the peripheral circuit region may be formed by the same step as a step of forming an element isolation region of the imaging region. In this case, the steps can be simplified.

In the peripheral circuit region, only a NMOS transistor, only a PMOS transistor, or a CMOS transistor may be formed. In this case, the number of implanting steps is reduced, enabling simplification of the steps.

The fifth method of the present invention is a method for manufacturing a solid-state imaging device provided with, on a semiconductor substrate, an imaging region in which a plurality of unit pixels respectively including photoelectric conversion sections and active regions are arranged, wherein in a step of forming an element isolation trench between the photoelectric conversion sections and between the respective photoelectric conversion regions and the respective active regions in the semiconductor substrate, a wall of the element isolation trench is tapered.

In the fifth method for manufacturing a solid-state imaging device, the element isolation trench to be the element isolation region is formed between the photoelectric conversion sections and between the respective photoelectric conversion sections and the respective active regions, so that sufficient breakdown voltage of the element isolation can be attained while the imaging region is miniaturized. Further, the wall portion of the element isolation trench is tapered, reducing stress generated at the boundary between the semiconductor substrate to be the photoelectric conversion section or the active region and the element isolation region. Accordingly, the leak current in the photoelectric conversion sections (for example, photodiode and the like) or the active regions (for example, the source region and the drain region of a transistor, and the like) can be reduced, the dark current is lowered, and white flaws are reduced in number.

The sixth method of the present invention is a method for manufacturing a solid-state imaging device provided with, on a semiconductor substrate, an imaging region in which a plurality of unit pixels respectively including photoelectric conversion sections and active regions are arranged, wherein in a step of forming an element isolation trench between the photoelectric conversion sections and between the respective photoelectric conversion regions and the respective active regions in the semiconductor substrate, an angle between a wall face of the element isolation trench and a surface of the semiconductor substrate is set within a range between 110° and 130°, both inclusive.

In the sixth method for manufacturing a solid-state imaging device, the element isolation trench to be the element isolation region is formed between the photoelectric conversion sections and between the respective photoelectric conversion sections and the respective active regions, so that sufficient breakdown voltage of the element isolation can be attained while the imaging region is miniaturized. Further, the angle between the wall face of the element isolation trench and the surface of the semiconductor substrate is set within the range between 110° and 130°, both inclusive. Accordingly, shearing stress generated at the boundary between the surface of the semiconductor substrate to be the photoelectric conversion section or the active region and the surface of the element isolation region can be minimized. Hence, the leak current induced due to stress generated due to the shearing stress can be reduced in the photoelectric conversion section (for example, photodiode and the like) or the active region (for example, the source region and the drain region of a transistor, and the like), and lowering of the dark current and the reduction in number of white flaws can be realized.

The fifth or sixth method for manufacturing a solid-state imaging device may further include the step of, after a first insulating film and a second insulting film different in kind from the first insulating film are deposited on the semiconductor substrate sequentially, pattering the first insulating film and the second insulating film before the step of forming the element isolation trench, wherein the step of forming the element isolation trench includes a step of etching the semiconductor substrate using the patterned first insulting film and the patterned second insulating film as a mask. In this case, a flow rate of an oxygen gas is preferably set to be 5% or lower of a flow rate of a chlorine gas in the step of etching the semiconductor substrate. This allows the wall of the element isolation trench to be tapered reliably.

In the fifth or sixth method, if a conductive type of the photoelectric conversion sections is n-type, a step of forming a p-type semiconductor layer at at least a part in contact with the element isolation trench in a region of the semiconductor substrate to be the photoelectric conversion sections is provided preferably after the step of forming the element isolation trench, while if a conductive type of the photoelectric conversion sections is p-type, a step of forming a n-type semiconductor layer at at least a part in contact with the element isolation trench in a region of the semiconductor substrate to be the photoelectric conversion sections is provided preferably after the step of forming the element isolation trench.

This reduces the dark current induced due to the interface state generated at the part where the silicon substrate is in contact with the element isolation region.

In the fifth or sixth method, it is preferable that the solid-state imaging device includes, on the semiconductor substrate, a peripheral circuit region including a drive circuit for operating the imaging region and element isolation structures are formed simultaneously in the peripheral circuit region and the imaging region.

This shortens the manufacturing steps.

In the fifth or sixth method, it is preferable that the solid-state imaging device includes, on the semiconductor substrate, a peripheral circuit region including a drive circuit for operating the imaging region and different element isolation structures are formed in the peripheral circuit region and the imaging region.

This allows the element isolation region provided in the peripheral circuit region to be smaller than the element isolation region provided in the imaging region, resulting in reduction in area of the peripheral circuit region.

In the fifth or sixth method, it is preferable to use only a NMOS transistor or only a PMOS transistor as a transistor provided in the peripheral circuit region.

This eliminates the need for an impurity implanting step, which has been necessary for manufacturing a solid-state imaging device, attaining a shortened process.

In the fifth or sixth method, it is preferable to use a CMOS transistor as a transistor provided in the peripheral circuit region.

This realizes a solid-state imaging device capable of high-speed charge reading.

A camera manufacturing method according to the present invention is a method for manufacturing a camera which employs the fifth or sixth method for manufacturing a solid-state imaging device of the present invention, and therefore, a camera capable of imaging at high resolutions can be realized.

The first solid-state imaging device of the present invention is a solid-state imaging device in which an imaging region in which a plurality of unit pixels are arranged is provided on a semiconductor substrate, each of the unit pixels including a plurality of element formation regions and an element isolation formation region located between the plurality of element formation regions, wherein in the element isolation formation region, a trench is formed in a part of the semiconductor substrate and a burying film is provided for burying the trench, and the trench is formed by removing a part of the semiconductor substrate using a protection film which covers the element formation regions of the semiconductor substrate and which includes an opening portion that exposes the element isolation formation region of the semiconductor substrate and a sidewall provided on a side face of the opening portion in the protection film as a mask.

In this solid-state imaging device, the trench is formed by removing a part of the semiconductor substrate using the sidewall as a mask. Accordingly, the width of the trench becomes smaller by the thickness of the sidewall than the width of the opening in the protection film. Consequently, even in the case where the opening of the protection film is formed to have a minimum opening width that can be formed by the currently available patterning method, a trench further narrower than the minimum opening width can be formed.

The element isolation power of the burying film for burying the trench is high even in the narrowed trench, thereby ensuring the element isolation power. The narrow trench width leads to extension of the distance between the element formation regions and the element isolation by the narrowed width. Accordingly, even if thermal stress is generated in the vicinity of the trench, the leak current flowing towards the element formation regions can be reduced. Hence, the dark current and white flaws are obviated.

A n-type impurity may be included in the element formation regions of the semiconductor substrate and a p-type impurity may be included in a surface portion of the trench in the element isolation formation region of the semiconductor substrate. In this case, the dark current is prevented from flowing towards an active region through the interface state generated by the formation of the trench. In detail, the p-type impurity is included in the vicinity of the surface of the trench in the semiconductor substrate, so that an energetic barrier is formed between the vicinity of the surface of the trench and the active region of the element, thereby restricting the movement of the carrier.

A silicon oxide film may be provided on a surface of the trench.

A level of the burying film may be higher than an upper face of the semiconductor substrate. In this case, though a wiring such as a gate wiring is formed on the burying layer, short circuit between wirings to be isolated therebetween is hard to occur. The reason thereof will be described below. The wirings are formed in such a manner that the semiconductor substrate and the burying film are covered with the conducting film and the conducting film is patterned. If the burying film is formed to a level lower than the upper face of the semiconductor substrate, it is difficult to remove a part of the conducting film which is located on the burying film. If this is the case, the wirings to be isolated form each other are liable to be in contact with each other through the conducting film that could not be removed. While, the higher burying film obviates this liability.

The second solid-state imaging device of the present invention is a solid-state imaging device in which an imaging region in which a plurality of unit pixels are arranged is provided on a semiconductor substrate, each of the unit pixels including a plurality of element formation regions and an element isolation region located between the plurality of element formation regions, wherein a part of the element isolation region of the semiconductor substrate is patterned, and an oxide film for element isolation that buries the patterned element isolation region, which is obtained by oxidizing a part of the semiconductor substrate which is exposed at a surface of the patterned element isolation region is provided.

In this way, the oxidation after the formation of the concave prevents a bird's beak from being formed, contemplating miniaturization of the device. Further, the oxide film for element isolation is formed by oxidizing the surface portion of the concave, and therefore, the oxide film is formed in a region apart from the element formation regions. This reduces stress in the region near the element formation regions and hardly generates film stress of the nitride film and the like and defects caused due to thermal treatment. Hence, dark current and white flaw which are generated due to defects are prevented while sufficient element isolation power is ensured.

A n-type impurity may be included in the element formation regions of the semiconductor substrate and a p-type impurity may be included in a surface portion of a concave in the semiconductor substrate in the element isolation region of the semiconductor substrate. In this case, the dark current is prevented from flowing towards an active region through the interface state generated by the formation of the concave. In detail, the p-type impurity is included in the vicinity of the surface of the concave in the semiconductor substrate, so that an energetic barrier is formed between the vicinity of the surface of the concave and the active region of the element, thereby restricting the movement of the carrier.

It is preferable that a level of the oxide film for element isolation is higher than an upper face of the semiconductor substrate. In this case, though a wiring such as a gate wiring is formed on the oxide film for element isolation, short circuit between wirings to be isolated therebetween hardly occurs. The reason thereof will be described below. The wirings are formed in such a manner that the semiconductor substrate and the oxide film for element isolation are covered with the conducting film and the conducting film is patterned. If the oxide film for element isolation is formed to a level lower than the upper face of the semiconductor substrate, it is difficult to remove a part of the conducting film which is located on the oxide film for element isolation. If this is the case, the wirings to be isolated from each other are liable to be in contact with each other through the conducting film that could not be removed. While, the higher burying film obviates this liability.

It is noted that if the above solid-state imaging device is employed in a camera, imaging at high resolutions is enabled.

The third solid-state imaging device of the present invention is a solid-state imaging device in which an imaging region in which a plurality of unit pixels are arranged is provided on a semiconductor substrate, each of the unit pixels including a plurality of element formation regions and an element isolation region located between the plurality of element formation regions, wherein in the element isolation region, a trench located in an upper part of the semiconductor substrate is formed, an element isolation film electrically isolating between the plurality of element formation regions is provided so as to cover at least an upper part of the trench, and a cavity is formed at a part within the trench.

In the element isolation formation region with the cavity formed therein, stress that the element isolation formation region gives to the semiconductor substrate is reduced. This stress reduction suppresses defect generation, resulting in lowering of the dark current and suppression of generation of white flaws. As well, the element isolation film and the cavity function to ensure sufficient breakdown voltage of the element isolation.

If the element isolation film covers an upper part of the cavity and includes a p-type impurity, the plurality of element formation regions are separated from each other electrically by the element isolation film, ensuring sufficient breakdown voltage of the element isolation.

If the element isolation film is a silicon oxide film that covers an upper part of the cavity, the plurality of element formation regions are separated from each other electrically by the silicon oxide film serving as an insulating film, ensuring sufficient breakdown voltage of the element isolation.

If the element isolation film is a TEOS film that buries the trench and the cavity is formed within a part of the of the TEOS film, the plurality of element formation regions are separated from each other electrically by the TEOS film serving as an insulating film, ensuring sufficient breakdown voltage of the element isolation.

When the above solid-state imaging device is employed in a camera, high resolutions can be attained.

The fourth solid-state imaging device of the present invention includes: a semiconductor substrate; and an imaging region provided on the semiconductor substrate in which a plurality of unit pixels respectively including photoelectric conversion sections and active regions are arranged, wherein an element isolation trench is formed between the photoelectric conversion sections and between the respective photoelectric conversion sections and the respective active regions, the element isolation trench having a tapered wall.

In the fourth solid-state imaging device, the element isolation trench to be the element isolation region is formed between the photoelectric conversion sections and between the respective photoelectric conversion sections and the respective active regions, so that sufficient breakdown voltage of the element isolation can be obtained while the imaging region is miniaturized. Further, the wall of the element isolation trench is tapered, reducing stress generated at the boundary between the semiconductor substrate to be the photoelectric conversion section or the active region and the element isolation region. Accordingly, the leak current in the photoelectric conversion section (for example, photodiodes and the like) or the active regions (for example, the source region and the drain region of a transistor, and the like) can be reduced, the dark current is lowered, and white flaws are reduced in number.

The fifth solid-state imaging device of the present invention includes: a semiconductor substrate; and an imaging region provided on the semiconductor substrate in which a plurality of unit pixels respectively including photoelectric conversion sections and active regions are arranged, wherein an element isolation trench is formed between the photoelectric conversion sections and between the respective photoelectric conversion sections and the respective active regions, a wall face of the element isolation trench forming an angle within a range between 110° and 130°, both inclusive, with respect to a surface of the semiconductor substrate.

In the fifth solid-state imaging device, the element isolation trench to be the element isolation region is formed between the photoelectric conversion sections and between the respective photoelectric conversion sections and the respective active regions, so that sufficient breakdown voltage of the element isolation can be obtained while the imaging region is miniaturized. Further, the angle between the wall face of the element isolation trench and the surface of the semiconductor substrate is kept in the range between 110° and 130°, both inclusive. Accordingly, shearing stress generated at the boundary between the surface of the semiconductor substrate to be the photoelectric conversion section or the active region and the surface of the element isolation region can be minimized. Hence, the leak current induced due to stress generated due to the shearing stress can be reduced in the photoelectric conversion sections (for example, photodiodes and the like) or the active regions (for example, the source region and the drain region of a transistor, and the like), the dark current is lowered, and white flaws are reduced in number.

In the fourth or fifth solid-state imaging device, if a conductive type of the photoelectric conversion sections is n-type, a p-type semiconductor layer is preferably provided at at least a part in contact with the element isolation trench in a region of the semiconductor substrate to be the photoelectric conversion sections, while if a conductive type of the photoelectric conversion sections is p-type, a n-type semiconductor layer is preferably provided at at least a part in contact with the element isolation trench in a region of the semiconductor substrate to be the photoelectric conversion sections.

With the above construction, the dark current induced due to the interface state generated at a part where the silicon substrate is in contact with the element isolation region can be reduced.

The fourth or fifth solid-state imaging device may further include a peripheral circuit region including a drive circuit for operating the imaging region in the semiconductor substrate, and the peripheral circuit region and the imaging region preferably have the same element isolation structure.

This simplifies the method for manufacturing a solid-sate imaging device.

The fourth or fifth solid-state imaging device may further include a peripheral circuit region including a drive circuit for operating the imaging region in the semiconductor substrate, and the peripheral circuit region and the imaging region preferably have different element isolation structures.

This allows the element isolation region provided in the peripheral circuit region to be smaller than the element isolation region provided in the imaging region, thereby reducing the area of the peripheral circuit region.

In the fourth or fifth solid-state imaging device, it is preferable that a transistor provided in the peripheral circuit region is only a n-type MOS transistor or only a p-type MOS transistor.

This eliminates the need for an impurity implanting step, which has been necessary in the solid-state imaging device manufacturing process, attaining a shortened process.

In the fourth or fifth solid-state imaging device, it is preferable that a transistor provided in the peripheral circuit region is a COMS transistor.

This realizes a solid-sate imaging device capable of high-speed charge reading.

A camera according to the present invention is a camera that employs the fourth or fifth solid-state imaging device of the present invention, and accordingly, imaging at high resolutions can be enabled.

### EFFECTS OF THE INVENTION

The solid-state imaging device and the method for manufacturing it according to the present invention are applicable to an element isolation formation region for isolating photodiodes and to an element isolation formation region for isolating a photodiode and an active region, and exhibit sufficient element isolation power with less stress generated, and have an excellent hump characteristic. Hence, the dark current can be suppressed and the number of white flaws can be reduced.

### BRIEF DESCRIPTION OF THE DRAWINGS

FIG. 1(a) to FIG. 1(f) are sections showing steps for forming an element isolation region in a solid-state imaging device manufacturing method in Embodiment 1.

FIG. 2(a) to FIG. 2(f) are sections showing steps for forming an element isolation region in a solid-state imaging device manufacturing method in Embodiment 2.

FIG. 3(a) to FIG. 3(d) are sections showing steps for forming an element isolation region in a solid-state imaging device manufacturing method in Embodiment 3.

FIG. 4(a) to FIG. 4(d) are sections showing steps for forming an element isolation region in a solid-state imaging device manufacturing method in Embodiment 4.

FIG. 5(a) to FIG. 5(e) are sections showing steps for forming an element isolation region in a solid-state imaging device manufacturing method in Embodiment 5.

FIG. 6(a) to FIG. 6(e) are sections showing steps for forming an element isolation region in a solid-state imaging device manufacturing method in Embodiment 6.

FIG. 7(a) to FIG. 7(e) are sections showing steps for forming an element isolation region solid-state imaging device manufacturing method in Embodiment 7.

FIG. 8(a) to FIG. 8(e) are sections showing steps of a solid-state imaging device manufacturing method in Embodiment 8.

FIG. 9 is a graph showing results obtained by simulating dependency, on a trench angle (=180° minus tapered angle θ), of stress (residual stress) caused at the boundary between a substrate 1 and an element isolation structure in Embodiment 8 where an element isolation insulating film 44 is buried in a trench 41.

FIG. 10 is a circuit diagram showing one example of a construction of a solid-state imaging device.

FIG. 11(a) to FIG. 11(f) are sections showing a process of forming an element isolation region in a conventional imaging device.

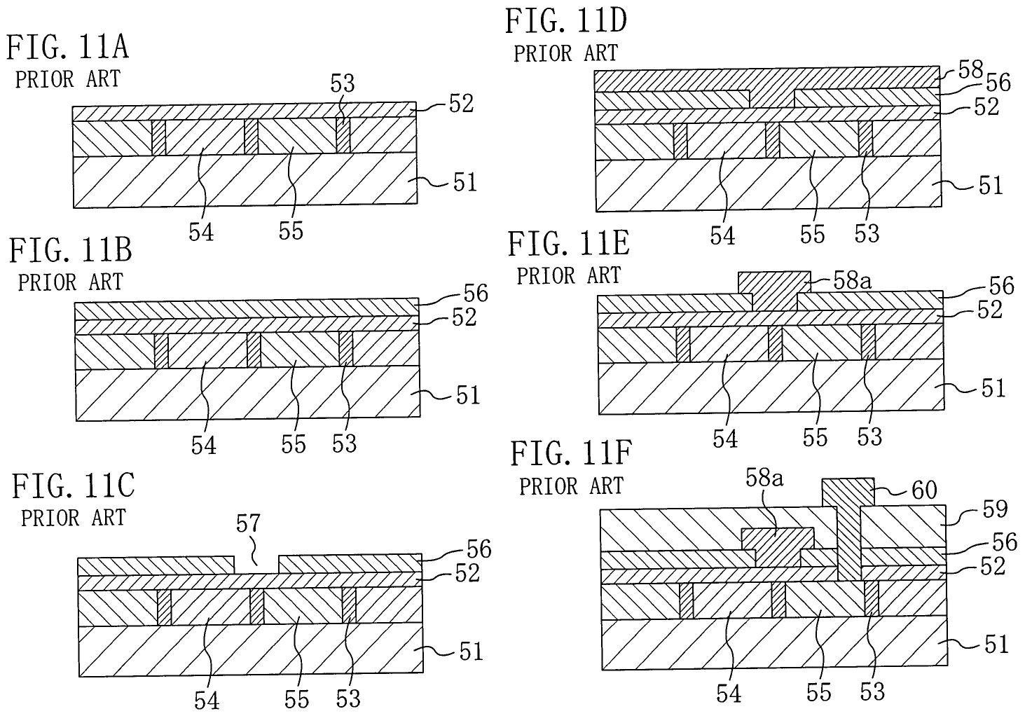

### EXPLANATION OF REFERENCE NUMERALS

1 semiconductor substrate
2 pad insulating film
3 anti-oxidizing film
4 opening
5 sidewall
6 trench
7 inner wall thermal oxide film
8 insulating film
9 photoelectric conversion section
10 active region
11 burying film
12 oxidizing film
13 gate insulting film
17 CVD oxide film
18 interlayer insulting film
19 signal wire
20 wiring pattern
21 LOCOS oxide film
30 implanted layer
31 trench
32 inner wall insulating film
33 cavity
34 silicon
35 oxide layer
36 TEOS film
37 cavity
41 trench
42 inner wall thermal oxide film
43 insulating film
44 element isolation insulating film
45 photoelectric conversion surface
46 photoelectric conversion bottom
51 semiconductor substrate
52 gate insulating film
53 element isolation region
54 photoelectric conversion section
55 drain region
56 CVD oxide film
57 trench
58 polysilicon film
58a wiring pattern
59 interlayer insulating film
60 signal wire

### BEST MODE FOR CARRYING OUT THE INVENTION

A solid-state imaging device according to embodiments of the present invention will be described below with reference to the drawings. Wherein, in the following embodiments, the case is described where the present invention is applied to an element isolation region between photodiodes or an element isolation region between a photodiode and an active region.

### Embodiment 1

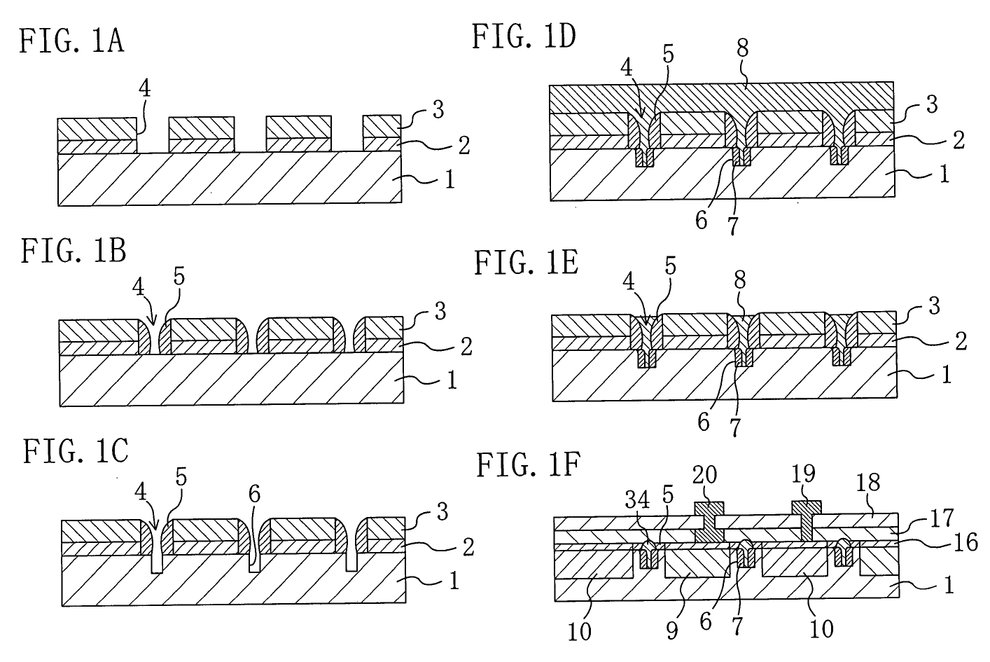

FIG. 1(a) to FIG. 1(f) are sections showing steps for forming an element isolation region in a solid-state imaging device manufacturing method according to Embodiment 1.

In the solid-state imaging device manufacturing method in the present embodiment, a pad insulating film 2 made of a silicon oxide film having a thickness of about 1 to 50 nm is formed on a semiconductor substrate 1 first in the step shown in FIG. 1(a). On the pad insulating film 2, an anti-oxidizing film 3 made of a silicon nitride film or the like having a thickness of 50 to 400 nm is formed. Then, a resist (not shown) including an opening portion in a predetermined region is formed on the anti-oxidizing film 3.

Thereafter, etching is performed using the resist as a mask to form an opening 4 passing through the pad insulating film 2 and the anti-oxidizing film 3 and allowing a predetermined region of the upper face of the semiconductor substrate 1 to be exposed. Then, the resist is removed. Herein, the width of the opening 4 is set to about 0.20 μm.

Next, in the step shown in FIG. 1(b), an anti-oxidizing film (not shown) made of a silicon nitride film or the like having a thickness of about 10 to 200 nm is deposited so as to cover the surface of the opening 4. Then, anisotropic dry etching is performed to the anti-oxidizing film to form a sidewall 5 having oxidization resistance on the side face of the opening 4. At that time, by changing the thicknesses of the anti-oxidizing film 3 and the anti-oxidizing film for the sidewall, the thickness of the sidewall 5 can be adjusted. It is noted that the silicon nitride film is used for the anti-oxidizing film 3 and the sidewall 5 in the present embodiment but an oxide film, a silicon film, or an oxynitride film may be used instead.

Subsequently, in the step shown in FIG. 1(c), selective etching is performed using the anti-oxidizing film 3 and the sidewall 5 as a mask for removing the upper part of the semiconductor substrate 1 to form a trench 6 having a depth of about 50 to 500 nm. Then, boron, which is a p-type impurity, is implanted over the substrate at an implantation energy of 5 KeV to 50 KeV with a dose amount of 1×10¹¹/cm² to 1×10¹⁵/cm².

Thereafter, in the step shown in FIG. 1(d), a part of the semiconductor substrate 1 which is exposed at the side face of the trench 6 is subjected to thermal oxidation to form an inner wall oxide film 7 having a thickness of about 40 nm. The formation of the inner wall thermal oxide film 7 allows an edge of the semiconductor substrate 1 which is exposed at the upper edge portion of the trench 6 to be rounded. Then, a burying film 8 made of an oxide film having a thickness of about 600 nm is deposited on the substrate so as to bury the trench 6 and the opening 4 and so as to cover the anti-oxidizing film 3. It is noted that the oxide film is used for the burying film 8 in the present embodiment but an oxynitride film may be used instead.

Next, in the step shown in FIG. 1(e), CMP is performed using the anti-oxidizing film 3 as a polishing stopper layer to polish and remove the upper part of the burying film 8.

Subsequently, in the step shown in FIG. 1(f), wet etching is performed to remove the anti-oxidizing film 3 and the upper part of the pad insulating film 2. This wet etching is performed under the condition that the etch rate of the silicon nitride film is higher than that of the silicon oxide film. Whereby, the anti-oxidizing film 3 and the sidewall 5, which are made of silicon nitride films, are removed deeper than the burying film 8 made of a silicon oxide film. Then, when the wet etching is stopped with the pad insulating film 2 left thin, the burying film 8 remains higher in level than the pad insulating film 2 and the sidewall 5.

Thereafter, ion is implanted into a desired region of the semiconductor substrate 1 to form a photoelectric conversion section 9 and an active region 10. Then, a gate insulating film 16, a CVD oxide film 17, an interlayer insulating film 18, a signal wiring 19, and a wiring pattern 20 including a gate electrode are formed by a known technique, thereby completing the semiconductor device of the present embodiment. Through the aforementioned steps, the process of the present embodiment is completed.

Effects obtained in the present embodiment will be described below.

In the present embodiment, the trench 6 is formed by etching using the sidewall 5 as a mask. Accordingly, the width of the trench 6 can be narrower by the thickness of the sidewall 5 than the width of the opening 4 (shown in FIG. 1(a) and the like). Thus, even in the case where the opening 4 is formed so as to have a minimum opening width that can be patterned by the currently available technique, the trench 6 narrower than the minimum opening width can be formed.

The burying film 8 for burying the trench 6 has high element isolation power even in the trench 6 of the narrowed width, ensuring the element isolation power. Further, by the narrowed width of the trench 6, the distance from the surface of the trench 6 to the photoelectric conversion section 9 and the active region 10 can be extended. Hence, even if thermal stress is generated in the vicinity of the trench 6 after the trench 6 is buried with the burying film 8, the leak current flowing towards the photoelectric conversion section 9 and the active region 10 can be reduced. In turn, the dark current and white flaws can be prevented. Referring to a concrete example, about 10000 white flaws were observed in an imaging device having a conventional STI while about 100 white flaws were observed in the imaging device of the present embodiment. Wherein, this comparison was carried out using the values measured under the condition that the imaging devices having one million pixels were operated at an output of 10 mV or higher.

Moreover, in the present embodiment, the p-type impurity is implanted after the trench 6 is formed. Accordingly, the dark current is prevented from flowing towards the active region through the interface state generated by the formation of the trench 6. In other words, doping of the p-type impurity in the vicinity of the surface of the trench 6 in the semiconductor substrate 1 allows an energetic barrier to be formed between the vicinity of the surface of the trench 6 and the active region of the element, restricting the movement of the carrier.

Furthermore, in the present embodiment, the inner wall thermal oxide film 7 is formed to round the edge of the semiconductor substrate 1 which is exposed at the upper edge portion of the trench. This prevents field concentration at the edge of the semiconductor substrate 1 in operation of the device.

In addition, the level of the burying film 8 is set higher than the upper face of the semiconductor substrate 1 in the present embodiment. This prevents short circuit between wirings such as a gate wring and the like to be insulated from each other even in the case where the wirings are formed on the burying film 8. The reason thereof will be described below. The wirings are formed in such a manner that the semiconductor substrate 1 and the burring film 8 are covered with the conducting film and the conducting film is patterned. If the burying film 8 is formed to a level lower than the upper face of the semiconductor substrate 1, it is difficult to remove a part of the conducting film which is located on the burying film 8. If this is the case, the wirings to be isolated from each other are liable to be in contact with each other through the conducting film that could not be removed. While, the higher burying film obviates this liability.

### Embodiment 2

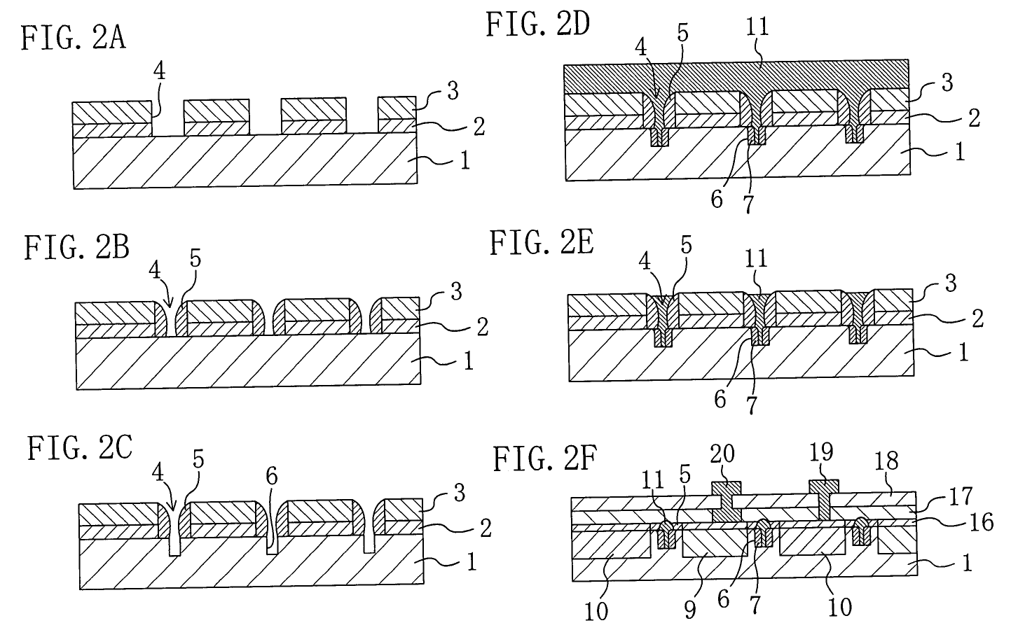

FIG. 2(a) to FIG. 2(f) are sections showing steps for forming an element isolation region in a solid-state imaging device manufacturing method according to Embodiment 2.

In the solid-state imaging device manufacturing method in the present embodiment, in the step shown in FIG. 2(a), a pad insulting film 2 made of a silicon oxide film having a thickness of about 1 to 50 nm is formed first on a semiconductor substrate 1. On the pad insulating film 2, an anti-oxidizing film 3 made of a silicon nitride film or the like film having a thickness of 50 to 400 nm is formed. Then, a resist (not shown) including an opening portion in a predetermined region is formed on the anti-oxidizing film 3.

Thereafter, etching is performed using the resist as a mask to form an opening 4 passing through the pad insulating film 2 and the anti-oxidizing film 3 and allowing a predetermined region of the upper face of the semiconductor substrate 1 to be exposed. Then, the resist is removed. Herein, the width of the opening 4 is set to about 0.2 μm.

Next, in the step shown in FIG. 2(b), an anti-oxidizing film (not shown) made of a silicon nitride film or the like having a thickness of about 10 to 200 nm is deposited so as to cover the surface of the opening 4. Then, anisotropic etching is performed to the anti-oxidizing film to form a sidewall 5 having oxidization resistance on the side face of the opening 4. At that time, by changing the thicknesses of the anti-oxidizing film 3 and the anti-oxidizing film for the sidewall, the thickness of the sidewall 5 can be adjusted. It is noted that the silicon nitride film is used for the anti-oxidizing film 3 and the sidewall 5 in the present embodiment but an oxide film, a silicon film, or an oxynitride film may be used instead.

Subsequently, in the step shown in FIG. 2(c), selective etching is performed using the anti-oxidizing film 3 and the sidewall 5 as a mask for removing the upper part of the semiconductor substrate 1 to form a trench 6 having a depth of about 50 to 500 nm. Then, boron, which is a p-type impurity, is implanted over the substrate at an implantation energy of 5 KeV to 50 KeV with a dose amount of 1×10¹¹/cm² to 1×10¹⁵/cm².

Thereafter, in the step shown in FIG. 2(d), a part of the semiconductor substrate 1 which is exposed at the side face of the trench 6 is subjected to thermal oxidation to form an inner wall oxide film 7 having a thickness of about 40 nm. The formation of the inner wall thermal oxide film 7 allows an edge of the semiconductor substrate 1 which is exposed at the upper edge portion of the trench 6 to be rounded. Then, a burying film 11 made of a silicon film having a thickness of about 600 nm is formed on the substrate so as to bury the trench 6 and the opening 4 and so as to cover the anti-oxidizing film 3. Herein, polysilicon or amorphous silicon is used for the burying film 11.

Next, in the step shown in FIG. 2(e), CMP is performed using the anti-oxidizing film 3 as a polishing stopper layer to polish and remove the upper part of the burying film 11.

Subsequently, in the step shown in FIG. 2(f), wet etching is performed to remove the anti-oxidizing film 3 and the upper part of the pad insulating film 2. This wet etching is performed under the condition that the etch rate of the silicon nitride film is higher than that of silicon. Whereby, the anti-oxidizing film 3 and the sidewall 5, which are made of silicon nitride films, are removed deeper than the burying film 11 made of silicon. Then, when the wet etching is stopped with the pad insulating film 2 left thin, the burying film 11 remains higher in level than the pad insulating film 2 and the sidewall 5.

Thereafter, ion is implanted into a desired region of the semiconductor substrate 1 to form a photoelectric conversion section 9 and an active region 10. Then, a gate insulating film 16, a CVD oxide film 17, an interlayer insulating film 18, a signal wiring 19, and a wiring pattern 20 including a gate electrode are formed by a known technique, thereby completing the semiconductor device of the present embodiment. Through the aforementioned steps, the process of the present embodiment is completed.

Effects obtained in the present embodiment will be described below.

In the present embodiment, the trench 6 is formed by etching using the sidewall 5 as a mask. Accordingly, the width of the trench 6 can be narrower by the thickness of the sidewall 5 than the width of the opening 4 (shown in FIG. 2(a) and the like). Thus, even in the case where the opening 4 is formed so as to have a minimum opening width that can be patterned by the currently available technique, the trench 6 narrower than the minimum opening width can be formed.

With the inner wall thermal oxide film 7 in the surface portion of the trench 6, high element isolation power can be ensured even with the trench 6 narrowed, Further, by the narrowed width of the trench 6, the distance from the surface of the trench 6 to the photoelectric conversion section 9 and the active region 10 can be extended. Hence, even if thermal stress is generated in the vicinity of the trench 6 after the trench 6 is buried with the burying film 11, the leak current flowing towards the photoelectric conversion section 9 and the active region 10 can be reduced. In turn, the dark current and white flaws can be prevented. Referring to a concrete example, about 10000 white flaws were observed in an imaging device having a conventional STI while about 100 white flaws were observed in the imaging device of the present embodiment. Wherein, this comparison was carried out using the values measured under the condition that the imaging devices having one million pixels were operated at an output of 10 mV or higher.

In the present embodiment, polysilicon or amorphous silicon is used as a material of the burying film 11. Polysilicon and amorphous silicon have coefficients of thermal expansion almost the same as that of the semiconductor substrate 1, and therefore, stress given from the burying film 11 to the semiconductor substrate 1 is further reduced.

Further, in the present embodiment, the p-type impurity is implanted after the trench 6 is formed. Accordingly, the dark current is prevented from flowing towards the active region through the interface state generated by the formation of the trench 6. In other words, doping of the p-type impurity in the vicinity of the surface of the trench 6 in the semiconductor substrate 1 allows an energetic barrier to be formed between the vicinity of the surface of the trench 6 and the active region of the element, restricting the movement of the carrier.

Furthermore, in the present embodiment, the inner wall thermal oxide film 7 is formed to round the edge of the semiconductor substrate 1 which is exposed at the upper edge portion of the trench. This prevents field concentration at the edge of the semiconductor substrate 1 in operation of the device.

In addition, the level of the burying film 11 is set higher than the upper face of the semiconductor substrate 1 in the present embodiment. This prevents short circuit between wirings such as a gate wring and the like to be insulated from each other even in the case were a wiring is formed on the burying film 11. The reason thereof will be described below. The wirings are formed in such a manner that the semiconductor substrate 1 and the burring film 11 are covered with the conducting film and the conducting film is patterned. If the burying film 11 is formed to a level lower than the upper face of the semiconductor substrate 1, it is difficult to remove a part of the conducting film where it is located on the burying film 11. If this is the case, the wirings to be isolated from each other are liable to be in contact with each other through the conducting film that could not be removed. While, the higher burying film obviates this liability.

### Embodiment 3

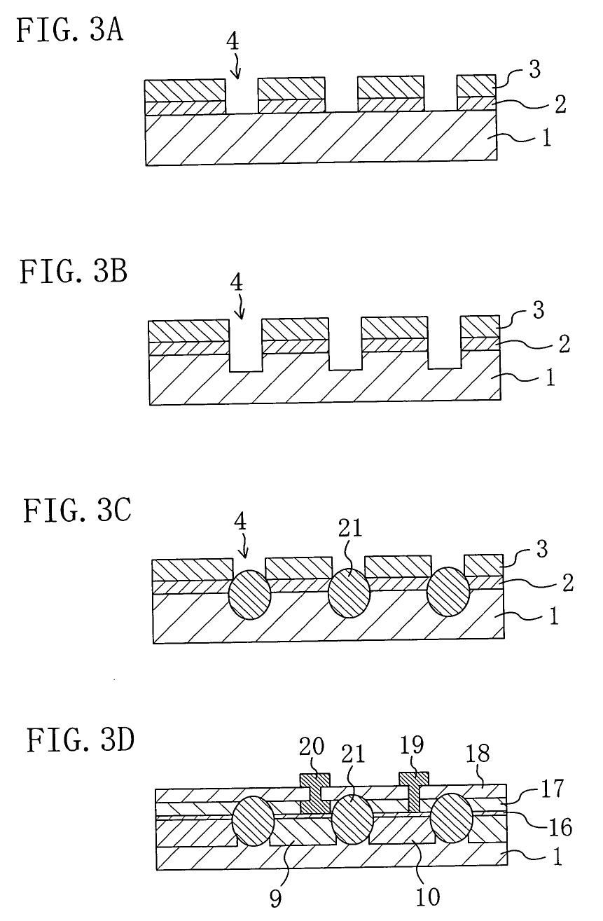

FIG. 3(a) to FIG. 3(d) are sections showing steps for forming an element isolation region in a solid-state imaging device manufacturing method according to Embodiment 3.

In the solid-state imaging device manufacturing method in the present embodiment, in the step shown in FIG. 3(a), a pad insulting film 2 made of a silicon oxide film having a thickness of about 1 to 50 nm is formed first on a semiconductor substrate 1. On the pad insulating film 2, an anti-oxidizing film 3 made of a silicon nitride film or the like having a thickness of 50 to 400 nm is formed. Then, a resist (not shown) including an opening portion in a predetermined region is formed on the anti-oxidizing film 3.

Thereafter, etching is performed using the resist as a mask to form an opening 4 passing through the pad insulating film 2 and the anti-oxidizing film 3 and exposing a predetermined region of the upper face of the semiconductor substrate 1. Then, the resist is removed. Herein, the width of the opening 4 is set to about 0.20 μm. It is noted that the width of the opening 4 is set narrower than a target width of an element isolation region, taking account that the element isolation region expands at formation of a LOCOS oxide film 21 (shown in FIG. 3(c)) thereafter. In this way, the width adjustment of the opening 4 reduces the surface area occupying the element isolation region. Hence, this method is useful when it is applied to a miniaturized MOS imaging device.

Subsequently, in the step shown in FIG. 3(b), the semiconductor substrate 1 is subjected to selective etching using the anti-oxidizing film 3 as a mask. At this time, the semiconductor substrate 1 is removed to a depth of about 10 to 100 nm to make the opening 4 deep. Then, boron, which is a p-type impurity, is implanted over the substrate at an implantation energy of 2.5 KeV to 50 KeV with a dose amount of 1×10¹¹/cm² to 1×10¹⁵/cm². This condition is adjusted so that electrons that induce the dark current through the interface state are bound.

Next, in the step shown in FIG. 3(c), a part of the semiconductor substrate 1 which is exposed at the surface of the opening 4 is subjected to selective thermal oxidation using the anti-oxidizing film 3 as a reinforced mask to form the LOCOS oxide film 21. The LOCOS oxide film 21 is formed so as to bury a part of the side face of the opening 4 where the semiconductor substrate 1 is exposed. Adjustment of height and shape of a protruding portion of the LOCOS oxide film 21 allows the conducting film to be removed with excellent controllability at formation of a gate insulating film by patterning the conducting film in a step thereafter. Hence, miniaturization becomes possible.

Thereafter, in the step shown in FIG. 3(d), wet etching is performed to remove the anti-oxidizing film 3 and the upper part of the pad insulting film 2. Alternatively, they may be removed in such a manner that after removing the anti-oxidizing film 3 and the pad insulating film 2 to some extent by CMP, the remaining part is removed by wet etching.

The width of a bird's beak may be adjusted, if it is long, by removing the bird's beak by wet etching so as to sufficiently ensure the area of the active region.

Subsequently, ion is implanted into a desired region of the semiconductor substrate 1 to form a photoelectric conversion section 9 and an active region 10. Then, a gate insulating film 16, a CVD oxide film 17, an interlayer insulating film 18, a signal wiring 19, and a wiring pattern 20 including a gate electrode are formed by a known technique, thereby completing the semiconductor device of the present embodiment.

Effects obtained in the present embodiment will be described below.

In the present embodiment, the LOCOS oxide film 21 is formed after the concave is formed by removing the upper part of the semiconductor substrate 1. This suppresses generation of a bird's beak, contemplating miniaturization of the device.

Further, the LOCOS oxide film 21 is formed after the formation of the concave. Thus, the operation region of the device can be ensured even with the LOCOS oxide film 21 formed.

The p-type impurity is implanted in the step shown in FIG. 3(b), so that the dark current is prevented from flowing towards the active region through the interface state generated by the formation of the concave. In other words, doping of the p-type impurity in the vicinity of the surface of the concave in the semiconductor substrate 1 forms an energetic barrier between the vicinity of the surface of the concave and the active region of the element, restricting the movement of the carrier.

The height of the LOCOS oxide film 21 is set higher than that of the semiconductor substrate 1 in the step shown in FIG. 3(d), so that short circuit of wirings such as a gate wiring and the like to be isolated from each other can be prevented even with a wiring formed on the LOCOS oxide film 21.

### Embodiment 4

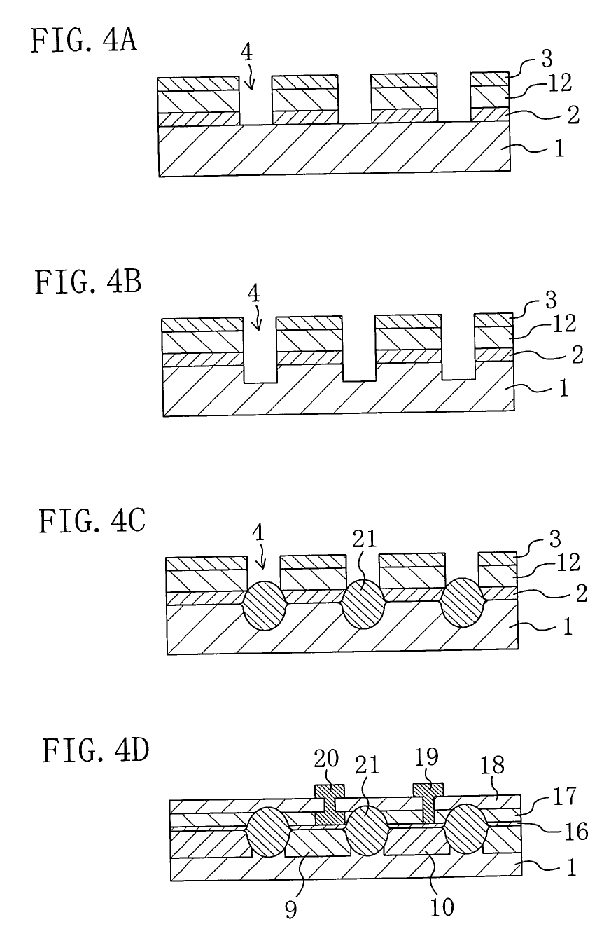

FIG. 4(a) to FIG. 4(d) are sections showing steps for forming an element isolation region in a solid-state imaging device manufacturing method according to Embodiment 4.

In the solid-state imaging device manufacturing method in the present embodiment, as shown in FIG. 4(a), a pad insulting film 2 made of a silicon oxide film having a thickness of about 1 to 50 nm is formed first on a semiconductor substrate 1. An oxidizing film 12 having a thickness of 10 to 30 nm is formed on the pad insulating film 2, and an anti-oxidizing film 3 made of a silicon nitride film or the like having a thickness of 50 to 400 nm is formed on the oxidizing film 12. Then, a resist (not shown) including an opening portion in a predetermined region is formed on the anti-oxidizing film 3.

Thereafter, etching is performed using the resist as a mask to form an opening 4 passing through the pad insulating film 2, the oxidizing film 12, and the anti-oxidizing film 3 and exposing a predetermined region of the upper face of the semiconductor substrate 1. Then, the resist is removed. Herein, the width of the opening 4 is set to about 0.2 μm. It is noted that the width of the opening 4 is set narrower than a target width of an element isolation region, taking account that the element isolation region expands at formation of a LOCOS oxide film 21 thereafter. In this way, the width adjustment of the opening 4 reduces the surface area occupying the element isolation region. Hence, this method is useful when it is applied to a miniaturized MOS imaging device.

Subsequently, in the step shown in FIG. 4(b), the semiconductor substrate 1 is subjected to selective etching using the anti-oxidizing film 3 as a mask. At this time, the semiconductor substrate 1 is removed to a depth of about 10 to 100 nm to make the opening 4 deep. Then, boron, which is a p-type impurity, is implanted over the substrate at an implantation energy of 2.5 KeV to 50 KeV with a dose amount of 1×10¹¹/cm² to 1×10¹⁵/cm². This condition is adjusted so that electrons that induce the dark current through the interface state are bound.

Next, in the step shown in FIG. 4(c), a part of the semiconductor substrate 1 which is exposed at the surface of the opening 4 is subjected to selective thermal oxidation using the anti-oxidizing film 3 as a reinforced mask to form the LOCOS oxide film 21. The LOCOS oxide film 21 is formed so as to bury a part of the side face of the opening 4 where the semiconductor substrate 1 is exposed. Adjustment of height and shape of a protruding portion of the LOCOS oxide film 21 allows the conducting film to be removed with excellent controllability at formation of a gate insulating film by patterning the conducting film in a step thereafter. Hence, miniaturization becomes possible.

Thereafter, in the step shown in FIG. 4(d), wet etching is performed to remove the anti-oxidizing film 3, the oxidizing film 12, and the upper part of the pad insulting film 2. Alternatively, they may be removed in such a manner that after removing the anti-oxidizing film 3, the oxidizing film 12, and the pad insulating film 2 to some extent by CMP, the remaining part is removed by wet etching.

The width of a bird's beak may be adjusted, if it is long, by removing the bird's beak by wet etching so as to sufficiently ensure the area of the active region.

Subsequently, ion is implanted into a desired region of the semiconductor substrate 1 to form a photoelectric conversion section 9 and an active region 10. Then, a gate insulating film 16, a CVD oxide film 17, an interlayer insulating film 18, a signal wiring 19, and a wiring pattern 20 including a gate electrode are formed by a known technique, thereby completing the semiconductor device of the present embodiment. Through the aforementioned steps, the process of the present embodiment is completed.

In the present embodiment, the same effects as in Embodiment 3 can be obtained. In addition, provision of the oxidizing film 12 between the pad insulating film 2 and the anti-oxidizing film 3 allows the boundary edge of the surface portion of the semiconductor substrate 1 against the element isolation region to be rounded. Thus, a hump characteristic (characteristic in leak current at the end portion of the element region) can be improved.

About 10000 white flaws were observed with a conventional STI as the element isolation region. While in the imaging device of the present embodiment, the white flaws were reduced to about 100 in number. Wherein, this comparison was carried out using the values measured under the condition that the imaging devices having one million pixels were operated at an output of 10 mV or higher.

### Embodiment 5

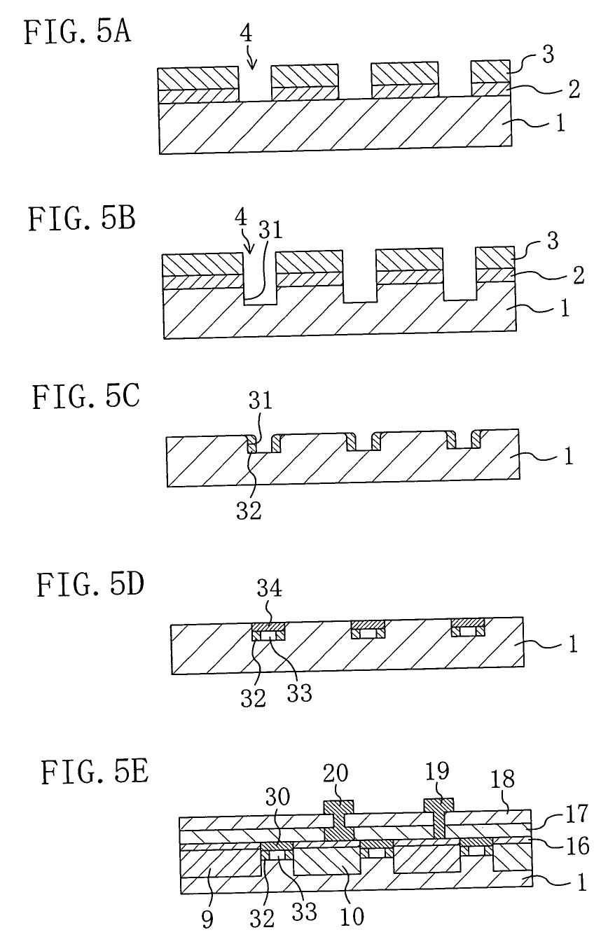

The present embodiment will be described on the assumption that an element isolation is used in a manufacturing process of a CMOS having a gate length of 0.3 μm or smaller. FIG. 5(a) to FIG. 5(e) are sections showing steps for forming an element isolation region in a solid-state imaging device manufacturing method according to Embodiment 5.

In the solid-state imaging device manufacturing method in the present embodiment, in the step showing in FIG. 5(a), a pad insulting film 2 made of a silicon oxide film having a thickness of about 1 to 50 nm is formed first on a semiconductor substrate 1. On the pad insulating film 2, an anti-oxidizing film 3 made of a silicon nitride film or the like having a thickness of about 50 to 400 nm is formed. Then, a resist (not shown) including an opening portion in a predetermined region is formed on the anti-oxidizing film 3.

Thereafter, etching is performed using the resist as a mask to form an opening 4 passing through the pad insulating film 2 and the anti-oxidizing film 3 and exposing a predetermined region of the upper face of the semiconductor substrate 1. Then, the resist is removed. Herein, the width of the opening 4 is set to about 0.2 μm.

Next, in the step shown in FIG. 5(b), the semiconductor substrate 1 is subjected to selective etching using the anti-oxidizing film 3 as a mask to form a trench 31 in the semiconductor substrate 1. At this time, the semiconductor substrate 1 is removed to a depth of about 50 to 500 nm. Then, boron, which is a p-type impurity, is implanted over the substrate at an implantation energy of 2.5 KeV to 50 KeV with a dose amount of 1×10¹¹/cm² to 1×10¹⁵/cm². This condition is adjusted so that electrons that induce the dark current through the interface state are bounded, thereby increasing the breakdown voltage of the isolation.

Subsequently, in the step shown in FIG. 5(c), a part of the semiconductor substrate 1 which is located on the side wall of the trench 31 is subjected to thermal oxidation to form an inner wall insulating film 32. This formation of the inner wall insulating film 32 remedies damage caused at the formation of the trench 31, reducing the leak current induced due to the interface state. Then, etching is performed to remove the pad insulating film 2 and the anti-oxidizing film 3.

It is noted that the inner wall insulating film 32 may be formed by CVD or the like rather than the thermal oxidation. Further, the inner wall insulating film 32 may be composed of plural layers of insulating films. In this case, damage caused on the side face of the trench 31 at the formation of the trench 31 can be covered.

Thereafter, in the step shown in FIG. 5(d), thermal treatment is performed in a nitrogen atmosphere at a temperature in the range between 1000° C. and 1200° C. When the thermal treatment is performed under this condition, thermal diffusion of silicon atoms is cause, so that the upper part of the trench 31 is covered with a silicon 34 with a cavity 33 formed inside the trench 31.

Next, in the step shown in FIG. 5(e), when a p-type ion is implanted into the upper part of the semiconductor substrate 1 where the element isolation region is located, an implanted layer 30 is formed. At this time, it is necessary to adjust the density so as to increase the breakdown voltage of the element isolation. In order to do so, B atoms are implanted at an implantation energy of 3 keV to 30 keV with a dose amount of 1×10¹¹/cm² to 1×10¹⁵/cm² in the present embodiment. Herein, necessary breakdown voltage of the element isolation depends on which elements the element isolation is to isolate. Namely, the implantation condition is adjusted for each of the element isolation between the photodiodes, the element isolations between the respective photodiodes and the respective active regions, and the element isolation between the active regions.

Thereafter, ion implantation is performed in a desired region of the semiconductor substrate 1 to form a photoelectric conversion section 9 and an active region 10. Then, a gate insulating film 16, a CVD oxide film 17, an interlayer insulating film 18, a signal wiring 19, and a wiring pattern 20 including a gate electrode are formed by a known technique, thereby completing the semiconductor device of the present embodiment. Through the aforementioned steps, the process of the present embodiment is completed.

In the present embodiment, the formation of the cavity 33 within the semiconductor substrate 1 enables formation of the element isolation region with no exotic material buried therein, reducing stress caused due to the thermal treatment. Further, this stress reduction suppresses generation of defects and white flaw and lowers the dark current. In addition, sufficient breakdown voltage of the element isolation is ensured by the intervention of the inner wall insulating film 32, the cavity 33, and the implanted layer 30.

About 10000 white flaws were observed with a conventional STI as the element isolation region. While in the imaging device of the present embodiment, the white flaws were reduced to about 100. Wherein, this comparison was carried out using the values measured under the condition that the imaging devices having one million pixels were operated at an output of 10 mV or higher.

### Embodiment 6

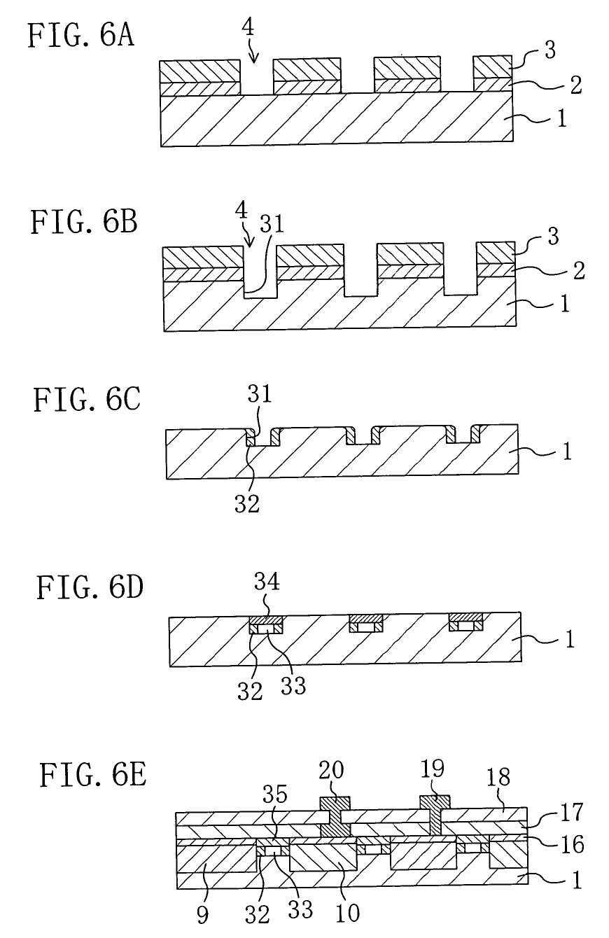

FIG. 6(a) to FIG. 6(e) are sections showing steps for forming an element isolation region in a solid-state imaging device manufacturing method according to Embodiment 6.

In the solid-state imaging device manufacturing method in the present embodiment, in the step shown in FIG. 6(a), a pad insulting film 2 made of a silicon oxide film having a thickness of about 1 to 50 nm is formed first on a semiconductor substrate 1. On the pad insulating film 2, an anti-oxidizing film 3 made of a silicon nitride film or the like having a thickness of 50 to 400 nm is formed. Then, a resist (not shown) including an opening portion in a predetermined region is formed on the anti-oxidizing film 3.

Thereafter, etching is performed using the resist as a mask to form an opening 4 passing through the pad insulating film 2 and the anti-oxidizing film 3 and exposing a predetermined region of the upper face of the semiconductor substrate 1. Then, the resist is removed. Herein, the width of the opening 4 is set to about 0.2 μm.

Subsequently, in the step shown in FIG. 6(b), the semiconductor substrate 1 is subjected to selective etching using the anti-oxidizing film 3 as a mask to form a trench 31 in the semiconductor substrate 1. At this time, the semiconductor substrate 1 is removed to a depth of about 50 to 500 nm. Then, boron, which is a p-type impurity, is implanted over the substrate at an implantation energy of 2.5 KeV to 50 KeV with a dose amount of 1×10¹¹/cm² to 1×10¹⁵/cm². This condition is adjusted so that electrons that induce the dark current through the interface state are bound.

Next, in the step shown in FIG. 6(c), the side wall of the trench 31 is subjected to thermal oxidation to form an inner wall insulating film 32, and etching is performed to remove the pad insulating film 2 and the anti-oxidizing film 3.

Thereafter, in the step shown in FIG. 6(d), thermal treatment is performed in a nitrogen atmosphere at a temperature in the range between 1000° C. and 1200° C. This causes thermal diffusion of silicon atoms in the surface portion of the semiconductor substrate 1, forming a cavity 33 within the element isolation region.

Subsequently, in the step shown in FIG. 6(e), the upper part of the semiconductor substrate 1 which is located in the element isolation region is subjected to thermal oxidation to form an oxide layer 35. This increases the breakdown voltage of the element isolation.

Next, ion is implanted into a desired region of the semiconductor substrate 1 to form a photoelectric conversion section 9 and an active region 10. Then, a gate insulating film 16, a CVD oxide film 17, an interlayer insulating film 18, a signal wiring 19, and a wiring pattern 20 including a gate electrode are formed by a known technique, thereby completing the semiconductor device of the present embodiment. Through the aforementioned steps, the process of the present embodiment is completed.

Effects obtained in the present embodiment will be described below.

In the present embodiment, the formation of the cavity 33 within the semiconductor substrate 1 enables formation of the element isolation region with no exotic material buried therein, reducing stress caused due to the thermal treatment. Further, this stress reduction suppresses generation of defects and white flaw and lowers the dark current. In addition, sufficient breakdown voltage of the element isolation is ensured by the intervention of the inner wall insulating film 32, the cavity 33, and the oxide layer 35.

About 10000 white flaws were observed with a conventional STI as the element isolation region. While in the imaging device of the present embodiment, the white flaws were reduced to about 100. Wherein, this comparison was carried out using the values measured under the condition that the imaging devices having one million pixels were operated at an output of 10 mV or higher.

### Embodiment 7

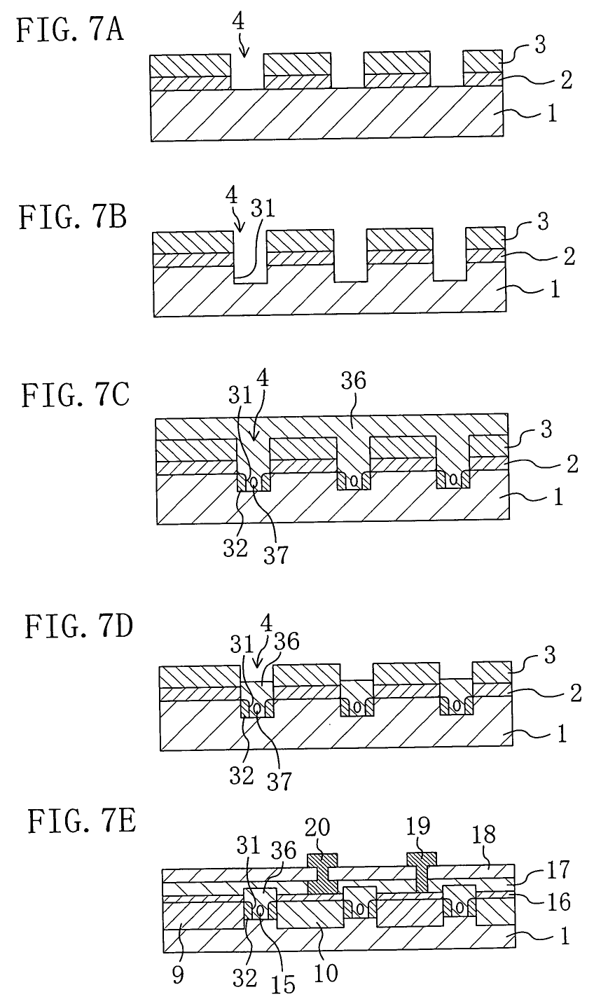

FIG. 7(a) to FIG. 7(e) are sections showing steps for forming an element isolation region in a solid-state imaging device manufacturing method according to Embodiment 7.

In the solid-state imaging device manufacturing method in the present embodiment, in the step shown in FIG. 7(a), a pad insulting film 2 made of a silicon oxide film having a thickness of about 1 to 50 nm is formed first on a semiconductor substrate 1. On the pad insulating film 2, an anti-oxidizing film 3 made of a silicon nitride film or the like having a thickness of 50 to 400 nm is formed. Then, a resist (not shown) including an opening portion in a predetermined region is formed on the anti-oxidizing film 3.

Thereafter, etching is performed using the resist as a mask to form an opening 4 passing through the pad insulating film 2 and the anti-oxidizing film 3 and exposing a predetermined region of the upper face of the semiconductor substrate 1. Then, the resist is removed. Herein, the width of the opening 4 is set to about 0.2 μm.

Subsequently, in the step shown in FIG. 7(b), the semiconductor substrate 1 is subjected to selective etching using the anti-oxidizing film 3 as a mask to form a trench 31 in the semiconductor substrate 1. At this time, the semiconductor substrate 1 is removed to a depth of about 50 to 500 nm. Then, boron, which is a p-type impurity, is implanted over the substrate at an implantation energy of 2.5 KeV to 50 KeV with a dose amount of 1×10¹¹/cm² to 1×10¹⁵/cm². This condition is adjusted so that electrons that induce the dark current through the interface state are bound.

Next, in the step shown in FIG. 7(c), a part of the semiconductor substrate 1 which is located at the side wall of the trench 31 is subjected to thermal oxidation to form an inner wall insulating film 32. It is noted that the inner wall insulating film 32 may be formed by CVD or the like rather than the thermal oxidation. Alternatively, the inner wall insulating film 32 may be formed of plural layers of insulating films. Then, a TEOS (Tetra Ethyl Oxosilane) film 36 for burying the opening 4 and the trench 31 and covering the anti-oxidizing film 3 is formed on the semiconductor substrate 1.

Thereafter, in the step shown in FIG. 7(d), polishing by CMP is performed to remove the TEOS film 36 to a level at the middle of the opening 4.

Subsequently, in the step shown in FIG. 7(e), the anti-oxidizing film 3 and the upper portion of the pad insulting film 2 are removed by etching, so that the height of the TEOS film 36 becomes higher than the upper face of the element formation region of the semiconductor substrate 1. Then, ion is implanted into a desired region of the semiconductor substrate 1 to form a photoelectric conversion section 9 and an active region 10. Then, a gate insulating film 16, a CVD oxide film 17, an interlayer insulating film 18, a signal wiring 19, and a wiring pattern 20 including a gate electrode are formed by a known technique, thereby completing the semiconductor device of the present embodiment. Through the aforementioned steps, the process of the present embodiment is completed.

Effects obtained in the present embodiment will be described below.

In the present embodiment, the formation of the cavity 37 within the element isolation enables reduction in stress that the TEOS film 36 of the element isolation gives to the semiconductor substrate 1. Further, this stress reduction suppresses generation of defects and white flaw and lowers the dark current. In addition, sufficient breakdown voltage of the element isolation is ensured by the intervention of the inner wall insulating film 32, the TEOS film 36, and the cavity 37. Wherein, if the depth of the trench 31 is two times larger than the width thereof, the cavity 37 can be formed easily.

About 10000 white flaws were observed with a conventional STI as the element isolation region. While in the imaging device of the present embodiment, the white flaws were reduced to about 2000 in number. Wherein, this comparison was carried out using the values measured under the condition that the imaging devices having one million pixels were operated at an output of 10 mV or higher. Further, the formation of the cavity 37 restricts the current to flow from the source region of an element to the drain region of an adjacent element through the element isolation, ensuring that a parasitic MOS transistor characteristic becomes 10 V or higher.

### Embodiment 8

A solid-state imaging device and a method for manufacturing it according to Embodiment 8 of the present invention will be described below with reference to the drawings.

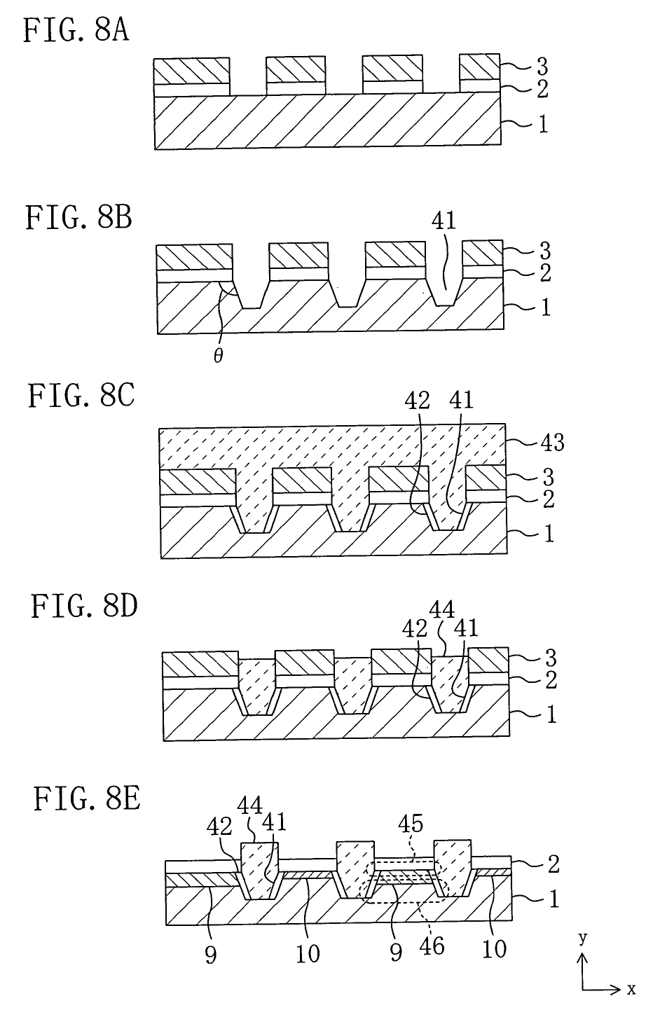

FIG. 8(a) to FIG. 8(e) are sections showing steps for manufacturing the solid-state imaging device according to Embodiment 8.

First, as shown in FIG. 8(a), a laminated body of a pad insulting film 2 serving as a first insulating layer and an anti-oxidizing film 3 serving as a second insulating layer is formed on a semiconductor substrate 1 made of silicon, for example. Then, the laminated body of the pad insulating film 2 and the anti-oxidizing film 3 is patterned. Specifically, an opening is formed by removing a predetermined region of the laminated body, namely, a part of the laminated body which is located on an element isolation region. Herein, the pad insulating film 2 is a silicon oxide film having a thickness of about 1 to 50 nm, for example, and the anti-oxidizing film 3 is a silicon nitride film having a thickness of about 50 to 400 nm, for example. In the present embodiment, a silicon film or a silicon oxynitride film may be used for the anti-oxidizing film 3, rather than the silicon nitride film.

Next, as shown in FIG. 8(b), the substrate 1 is subjected to dry etching using the patterned pad insulating film 2 and the patterned anti-oxidizing film 3 as a mask to form an element isolation trench (hereinafter referred to as a trench) 41. At this time, the wall of the trench 41 is tapered to reduce local stress in the element isolation region. Further, as will be described later, the angle (tapering angle θ) between the wall face of the trench 41 and the surface of the substrate 1 is preferably in the range between 110° and 130°, both inclusive.

Specifically, in the dry etching to the substrate 1, the flow rate of an oxygen gas is set to be 5% or lower of the flow rate of a chlorine gas (or chlorine containing gas). This allows a reaction product generated due to etching to adhere to the wall face of the trench 41 at the formation of the trench 41, tapering the wall of the trench 41. Wherein, the reaction product adhered to the wall face of the trench 41 is removed by etching after the dry etching.

Thereafter, a p-type impurity is implanted into the vicinity of the trench 41 in the substrate 1. At this time, the implantation energy and the dose amount are adjusted so that electrons from the dark current induced due to the interface state can be bounded. Specifically, B (boron) atoms are implanted at an implantation energy of about 5 keV to 50 keV with a dose amount of about 1×10¹¹/cm² to 1×10¹⁵/cm² in the present embodiment.

Subsequently, as shown in FIG. 8(c), a part of the substrate 1 which is to be a wall of the trench 41 is subjected to thermal oxidation to form an inner wall oxide film 42. Then, an insulating film 43 is deposited over the entirety of the substrate 1 so as to bury the trench 41. Herein, a silicon oxide film or a silicon oxynitride film may be used for the insulting film 43.

Next, as shown in FIG. 8(d), the insulating film 43 is polished by CMP (chemical mechanical polishing) using the anti-oxidizing film 3 as a polishing stopper layer to form an element insulation insulting film 44 in the trench 41.

Thereafter, as shown in FIG. 8(e), wet etching is performed to remove the anti-oxidizing film 3 (and a part of the pad insulating film 2). This enables formation of an element isolation structure in which the element isolation insulating film 44 is buried in the trench 41 having a narrower width than the element isolation region, realizing stress lowering and sufficient breakdown voltage of the element isolation. Then, a photoelectric conversion section (for example, photodiode) 9 and an active region (for example, the source region and the drain region of a transistor) 10, which compose a pixel of the imaging region, are formed in each portion interposed by the trenches 41, that is, the element isolation regions of the substrate 1.

As described above, in the present embodiment, the trench 41 to be the element isolation region is formed between the photoelectric conversion sections 9 and between the respective photoelectric conversion sections 9 and the respective active regions 10, so that sufficient breakdown voltage of the element isolation can be obtained while the imaging region is miniaturized. Further, with the tapered wall of the trench 41, stress generated at the boundary between the substrate to be the photoelectric conversion section 9 or the active region 10 and the trench 41 (namely, the element isolation region) can be reduced. Hence, the leak current in the photoelectric conversion section 9 (for example, photodiode or the like) or the active region 10 (for example, the source region and the drain region of a transistor) can be reduced, the dark current can be lowered, and the number of white flaws can be reduced.

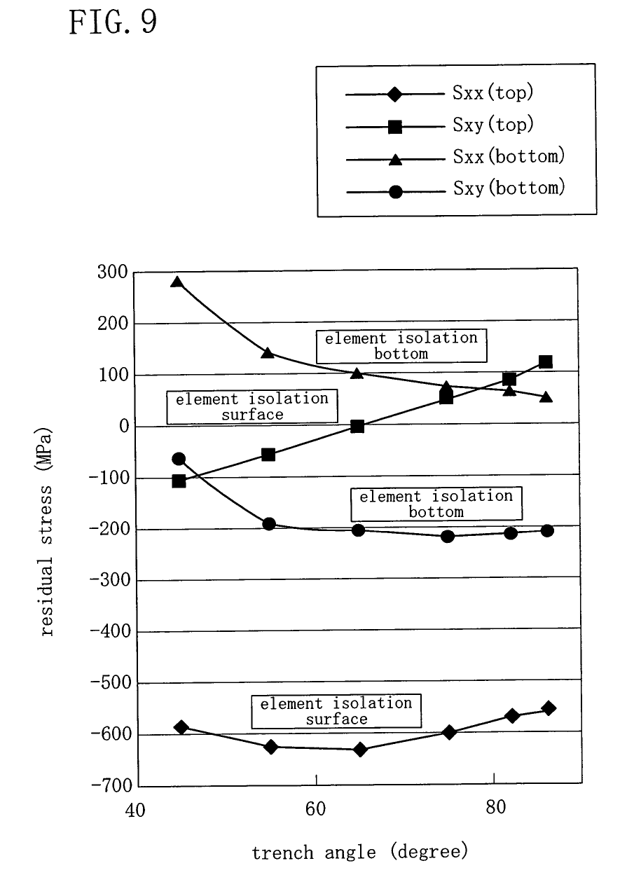

FIG. 9 is a graph showing results obtained by simulating dependency, on a trench angle (=180° minus tapered angle θ), of stress (residual stress) caused at the boundary between the substrate 1 and the element isolation structure in the present embodiment where the element isolation insulating film 44 is buried in the trench 41. Wherein, in the present embodiment, a direction in parallel with the principle plane of the substrate 1 is defined as an x direction while a direction perpendicular to the principle plane of the substrate 1 is defined as a y direction, as shown in FIG. 8(e). Herein, stress that the photoelectric conversion section 9 receives is classified into compressive stress and shearing stress which are received from the element isolation insulating films 44 on both sides of the photoelectric conversion section 9. The compressive stress is force applied in the x direction to the photoelectric conversion section 9 when the element isolation insulting film 44 expands in volume in the x direction and is indicated as Sxx in FIG. 9. On the other hand, the sharing stress is force applied in the y direction to the photoelectric conversion section 9 when the element isolation insulating film 44 expands in volume in the x direction, which is force pushing upward the photoelectric conversion section 9, and is indicated as Sxy in FIG. 9. Part where Sxx and Sxy exhibits remarkably high values are at a photoelectric conversion surface 45 and a photoelectric conversion bottom 46 shown in FIG. 8(e). Specifically, FIG. 9 shows results where Sxx(top) and Sxy(top), which are the peak values of Sxx and Sxy in the photoelectric conversion surface 45, respectively, and Sxx(bottom) and Sxy(bottom), which are the peak values of Sxx and Sxy in the photoelectric conversion bottom 46, respectively, are plotted at various trench angles.

As shown in FIG. 9, in the range of the tapered angle θ between 110° and 130°, stress generated at the boundary portion between the surface in the element isolation structure and the surface of the substrate 1 is reduced. Namely, in this range, the searing stress at the boundary portion between the surface of the substrate 1 to be the photoelectric conversions section 9 or the active region 10 and the surface in the element isolation structure can be minimized, resulting in reduction in leak current induced due to stress generated due to the shearing stress in the photoelectric conversion section 9 or the active region 10 and realizing lowering of the dark current and reduction of white flaws. Specifically, when the element isolation structures in the present embodiment in which the wall of the trench 41 is tapered and in the conventional STI structure in which the wall portion is not tapered were used in a solid-sate imaging device with one million pixels at output power of 10 mV or higher, about 10000 white flaws were observed in the conventional STI structure while the number of white flaws was reduced to about 5000 or less in the element isolation structure in the present embodiment. Further, when the tapered angle θ is set within the range between 110° and 130° in the element isolation structure in the present embodiment, the number of white flaws can be suppressed to about 1000.

It is noted that in the present embodiment, if the photoelectric conversion section 9 has the n-type conductivity, it is preferable to provide, after the formation of the trench 41, a p-type semiconductor layer at at least a part in contact with the trench 41 in the region of the substrate 1 to be the photoelectric conversion section 9. To the contrary, if the photoelectric conversion section 9 has the p-type conductivity, it is preferable to provide, after the formation of the trench 41, a n-type semiconductor layer at at least a part in contact with the trench 41 in the region of the substrate 1 to be the photoelectric conversion section 9. With this construction, the dark current induced due to the interface state generated at the part of the substrate 1 in contact with the element isolation region can be reduced.

### Other Embodiments

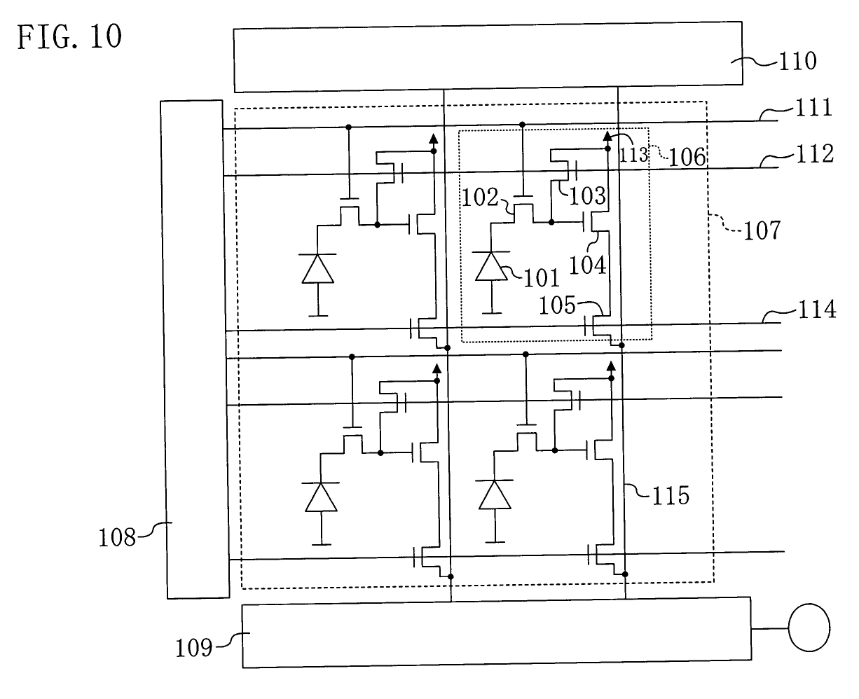

In the above embodiments, the element isolation of the present invention is applied to the element isolation in each pixel 106 shown in FIG. 10. However, the element isolation of the present invention is applicable to an element isolation in a peripheral circuit such as the vertical shift register 108, the horizontal shift register 109, the timing generator 110, and the like. In this case, steps for forming the element isolations can be shortened.

Further, if the solid state imaging device includes on the substrate thereof the peripheral circuit region including the drive circuit for operating the imaging region in the above embodiments, the peripheral circuit region and the imaging region may have different element isolation structures. With this arrangement, the element isolation region provided in the peripheral circuit region can be smaller than the element isolation region provided in the imaging region, reducing the area of the peripheral circuit region.

It is noted that the MOSFETs in the imaging region shown in FIG. 10 are all of n-type. Therefore, design of the peripheral circuit by only NMOSFETs eliminates the need for an implantation step, shortening the steps.

The use of a CMOS transistor in the peripheral circuit increases the speed of charge reading.

Incorporation of the solid-state imaging device of the present invention into a camera enables imaging at high resolutions.

It is also noted that the imaging device is formed on a silicon substrate in the above embodiments, but the present invention is applicable to the case where the imaging device is formed on a semiconductor substrate made of GaAs or the like.

### INDUSTRIAL APPLICABILITY

As described above, the solid-state imaging device and the method for manufacturing it can provide an element isolation having sufficient element isolation power and an excellent hump characteristics with low stress generated, and can attain low dark current and less white flaws. Thus, they have much industrial applicability.

1-62. (canceled)

63. A method for manufacturing a solid-state imaging device in which an imaging region in which a plurality of unit pixels are arranged is provided on a semiconductor substrate, each of the unit pixel including a plurality of element formation regions and an element isolation formation region located between the plurality of element formation regions, the method comprising:
a step (a) of forming, on the semiconductor substrate, a protection film including an opening portion that exposes the element isolation formation region of the semiconductor substrate;
a step (b) of forming a trench by removing a part of the element isolation formation region of the semiconductor substrate by etching using the protection film as a mask;
a step (c) of removing the protection film after the step (b); and
a step (d) of performing thermal treatment in an atmosphere including hydrogen at a temperature in a range between 1000° C. and 1300° C., both inclusive, after the step (b).

64. The method for manufacturing a solid-state imaging device of claim 63,
wherein in the step (d), a semiconductor film of a semiconductor material composing the semiconductor substrate is formed so as to cover an upper part of the trench by the thermal treatment, and
the method further comprising: a step (e) of implanting an impurity having a conductivity type different from that of the element formation regions into the semiconductor film after the step (d).

65. The method for manufacturing a solid-state imaging device of claim 63,
wherein in the step (d), a semiconductor film of a semiconductor material composing the semiconductor substrate is formed so as to cover an upper part of the trench by the thermal treatment, and
the method further comprising: a step (f) of oxidizing the semiconductor film after the step (d).

66. The method for manufacturing a solid-state imaging device of claim 63, further comprising:
a step (g) of subjecting a side face portion of the trench in the semiconductor substrate to thermal oxidation after the step (b) and before the step (d).

67. The method for manufacturing a solid-state imaging device of claim 63, further comprising:
a step (h) of forming an insulating film on a side face of the trench after the step (b) and before the step (d).

68. The method for manufacturing a solid-state imaging device of claim 63,
wherein a peripheral circuit region including a drive circuit for operating the imaging region is provided beside the imaging region in the semiconductor substrate, and
an element isolation region of the peripheral circuit region is formed by the same step as a step of forming an element isolation region of the imaging region.

69. The method for manufacturing a solid-state imaging device of claim 68,
wherein in the peripheral circuit region, only a NMOS transistor, only a PMOS transistor, or a CMOS transistor is formed.

70. A method for manufacturing a solid-state imaging device in which an imaging region in which a plurality of unit pixels are arranged is provided on a semiconductor substrate, each of the unit pixel including a plurality of element formation regions and an element isolation formation region located between the plurality of element formation regions, the method comprising:
a step (a) of forming, on the semiconductor substrate, a protection film including an opening portion that exposes the element isolation formation region and a region located beside the element isolation formation region of the semiconductor substrate;
a step (b) of forming a sidewall on a side face of the opening in the protection film;
a step (c) of forming a trench in the element isolation formation region in the semiconductor substrate by etching using the protection film and the sidewall as a mask; and
a step (d) of forming an element isolation region by burying the trench with a burying film.

71. The method for manufacturing a solid-state imaging device of claim 70, further comprising the step of:
oxidizing a surface portion of the trench in the semiconductor substrate after the step (c) and before the step (d).

72. The method for manufacturing a solid-state imaging device of claim 63,
wherein in the step (a), a width of the opening portion is narrower than a width of the element isolation formation region.

73. A method for manufacturing a solid-state imaging device in which an imaging region in which a plurality of unit pixels are arranged is provided on a semiconductor substrate, each of the unit pixel including a plurality of element formation regions and an element isolation formation region located between the plurality of element formation regions, the method comprising:
a step (a) of forming, on the semiconductor substrate, a protection film including an opening portion that exposes a part of the element isolation formation region of the semiconductor substrate;
a step (b) of forming a trench having a depth two time larger than a width thereof by removing a part of the element isolation formation region of the semiconductor substrate by etching using the protection film as a mask; and
a step (c) of forming a TEOS film for burying the trench by CVD after the step (b).

74. A method for manufacturing a solid-state imaging device provided with, on a semiconductor substrate, an imaging region in which a plurality of unit pixels respectively including photoelectric conversion sections and active regions are arranged,
wherein in a step of forming an element isolation trench between the photoelectric conversion sections and between the respective photoelectric conversion regions and the respective active regions in the semiconductor substrate, a wall of the element isolation trench is tapered.

75. The method for manufacturing a solid-state imaging device of claim 74, comprising the step of, after a first insulating film and a second insulting film different in kind from the first insulating film are deposited on the semiconductor substrate sequentially, pattering the first insulating film and the second insulating film before the step of forming the element isolation trench,
wherein the step of forming the element isolation trench includes a step of etching the semiconductor substrate using the patterned first insulting film and the patterned second insulating film as a mask.

76. The method for manufacturing a solid-state imaging device of claim 75,
wherein in the step of etching the semiconductor substrate, a flow rate of an oxygen gas is set to be 5% or lower of a flow rate of a chlorine gas.

77. A solid-state imaging device in which an imaging region in which a plurality of unit pixels are arranged is provided on a semiconductor substrate, each of the unit pixels including a plurality of element formation regions and an element isolation formation region located between the plurality of element formation regions,
wherein in the element isolation formation region, a trench is formed in a part of the semiconductor substrate and a burying film is provided for burying the trench, and
the trench is formed by removing a part of the semiconductor substrate using a protection film which covers the element formation regions of the semiconductor substrate and which includes an opening portion that exposes the element isolation formation region of the semiconductor substrate and a sidewall provided on a side face of the opening portion in the protection film as a mask.

78. A solid-state imaging device in which an imaging region in which a plurality of unit pixels are arranged is provided on a semiconductor substrate, each of the unit pixels including a plurality of element formation regions and an element isolation region located between the plurality of element formation regions,
wherein in the element isolation region, a trench located in an upper part of the semiconductor substrate is formed, an element isolation film electrically isolating between the plurality of element formation regions is provided so as to cover at least an upper part of the trench, and a cavity is formed at a part within the trench.

79. A solid-state imaging device comprising:
a semiconductor substrate; and
an imaging region provided on the semiconductor substrate in which a plurality of unit pixels respectively including photoelectric conversion sections and active regions are arranged,
wherein an element isolation trench is formed between the photoelectric conversion sections and between the respective photoelectric conversion sections and the respective active regions, the element isolation trench having a tapered wall.

80. A solid-state imaging device comprising:
a semiconductor substrate; and
an imaging region provided on the semiconductor substrate in which a plurality of unit pixels respectively including photoelectric conversion sections and active regions are arranged,
wherein an element isolation trench is formed between the photoelectric conversion sections and between the respective photoelectric conversion sections and the respective active regions, a wall face of the element isolation trench forming an angle within a range between 110° and 130°, both inclusive, with respect to a surface of the semiconductor substrate.

81. The method for manufacturing a solid-state imaging device of claim 70,
wherein the element formation regions of the semiconductor substrate include a n-type impurity, and
the method further comprising the step of implanting a p-type ion into a surface portion of the trench in the semiconductor substrate after the step (c) and before the step (d).

82. The method for manufacturing a solid-state imaging device of claim 63,
wherein a part of the element formation regions of the semiconductor substrate includes a n-type impurity,
the method further comprising:
a step (i) of implanting a p-type ion into a surface portion of the trench in the semiconductor substrate after the step (b) and before the step (d).

83. A camera characterized by using the solid-state imaging device of claim 77.

84. A camera characterized by using the solid-state imaging device of claim 78.

85. A camera characterized by using the solid-state imaging device of claim 79.

86. A camera characterized by using the solid-state imaging device of claim 80.
